(19) United States
(12) Patent Application Publication
(10) Pub. No.: US 2026/0246240 A1
(43) Pub. Date: Aug. 20, 2026

(54) SEMICONDUCTOR LASER DEVICE AND OPTICAL APPARATUS

(71) Applicant: Ushio Denki Kabushiki Kaisha, Tokyo (JP)

(72) Inventors: Masato Hagimoto, Tokyo (JP); Tadashi Okumura, Tokyo (JP); Yutaka Inoue, Tokyo (JP)

(73) Assignee: Ushio Denki Kabushiki Kaisha, Tokyo (JP)

(21) Appl. No.: 19/644,488

(22) Filed: Apr. 10, 2026

Related U.S. Application Data
(63) Continuation of application No. 17/559,239, filed on Dec. 22, 2021, now abandoned.

(30) Foreign Application Priority Data
Dec. 24, 2020 (JP) 2020-215677

(51) Int. Cl. H01S 5/40; G03B 21/20; H01S 5/026; H01S 5/042; H01S 5/22; H01S 5/323; H01S 5/343

(52) U.S. Cl. CPC H01S 5/4031; G03B 21/2033; H01S 5/026; H01S 5/042; H01S 5/22; H01S 5/32325; H01S 5/34326; H01S 5/4087

(57) ABSTRACT

A semiconductor laser device includes: a substrate having a main surface; a first cladding layer with a first conductive type and a second cladding layer with a second conductive type, which are stacked over the main surface of the substrate; and a light-emitting layer that is formed between the first cladding layer and the second cladding layer, and is formed on a first surface parallel to the main surface of the substrate; the light-emitting layer has a plurality of light-emitting regions emitting laser beams in a red range; and among the laser beams emitted from the light-emitting regions, the difference between a peak wavelength in an optical spectrum of at least one laser beam and a peak wavelength in an optical spectrum of the other laser beams is 1.5 nm or more.

### FIELD OF THE INVENTION

The present invention relates to a semiconductor laser device and an optical apparatus using the semiconductor laser device.

### BACKGROUND OF THE INVENTION

In recent years, a market of display apparatuses including projectors using semiconductor laser devices (hereinafter simply refers to semiconductor LD or LD) has been expanding.

Moreover, in recent years, reality technologies such as augmented reality (AR), virtual reality (VR), mixed reality (MR) and substitutional reality (SR) have found practical application in various fields. These technologies have been used to commercialize display apparatuses such as head mount display (HMD), head-up display (HMD) and AR glasses.

For example, a head mounted display (HMD) is known to involve the technologies including a light source having three colors of laser beams (red, green and blue), MEMS (Micro Electro Mechanical Systems) that creates an image as a spatial modulator element for image display and a waveguide that transmits the image to project it onto, for example, retinas. This system using MEMS is noted for its advantages in wide color gamut, high resolution and wide viewing angle. Meanwhile, in order to achieve high performance images with a wide color gamut, high resolution and a wide viewing angle, multi-beam LDs (multiple semiconductor laser devices) are used for each RGB color; however, each of the colors has the same wavelength. If all the beams constituting each color emit light having the same wavelength, the image quality is degraded due to the interference of the laser beams.

Patent reference 1 discloses a technology that aims to broaden a spectral width by radiating laser beams of three colors (RGB) having short pulse widths of 15 ns (nanoseconds) or less for generating AR or VR images, etc. For example, the spectral width is 1.0 to 5.0 nm at full width at half maximum (FWHM). The technology also aims to suppress light and dark interference fringes (Newtonian ring) in the waveguide to improve the image quality.
Patent reference 1: US 2019/0372306A1

In order to improve image quality (resolution and a frame rate), transverse single-mode LDs with a monolithic structure that independently drives multi-emitters (multiple light-emitting sections) at a narrow pitch are requested. Unfortunately, transverse single-mode lasers have a narrow wavelength spectrum and high interference, posing a problem of image quality degradation.

In addition, for high performance display devices, it is necessary to suppress the interference of laser beam and further improve visual sensitivity and image quality such as a wide color gamut, high resolution and a wide viewing angle. For the further improvement of the visual sensitivity and image quality, for example, the light source using laser beams of RGB three colors is desirably a semiconductor laser device that can emit multiple laser beams with different oscillation wavelengths in each color from the viewpoint of suppressing the image quality degradation caused by the interference of laser beams as described above.

In Patent reference 1, each of the three RGB colors is multi-beamed; however, the wavelength of the laser light of each color is the same. As mentioned above, if the wavelengths of all the beams are the same, for example, when passing through a waveguide, the laser beams interfere with each other in the waveguide, causing light and dark interference fringes (Newtonian rings) to appear in the image, resulting in poor image quality. Accordingly, there is room for improvement in terms of image quality.

In addition, Patent reference 1 describes that the spectral width can be broadened by a wavelength modulation of applying high-frequency superimposition having a pulse width of 15 ns or less to the LD driving current. However, according to the inventors' study, providing a pulse width of 15 ns or less requires a dedicated drive circuit because it is a very short pulse width. In addition, applying high-frequency superimposition to LDs requires the impedance matching to the LDs, thereby the dedicated drive circuit needs to be custom-designed in accordance with the characteristics of the LD elements, significantly increasing the cost. Furthermore, when expanding the spectral width using only high-frequency superimposition, driving a pulse with its pulse width shorter than 15 ns is necessary to expand the full width at half maximum (expansion of 1.5 nm or more) such that no fringing occurs in the image; however, a drive circuit that accomplishes the high current drive and the short pulse drive is technically challenging and a major constraint in terms of feasibility.

### SUMMARY OF THE INVENTION

It is an object of the present invention to provide a semiconductor laser device that contributes to the improvement of visual sensitivity and image quality. Other issues and new features will become evident from the description in the present specification and the drawings.

The semiconductor laser device includes:
a substrate having a main surface;
a first cladding layer with a first conductive type and a second cladding layer with a second conductive type, which are stacked over the main surface of the substrate; and
a light-emitting layer that is formed between the first cladding layer and the second cladding layer, and is formed on a first surface parallel to the main surface of the substrate;
the light-emitting layer has a plurality of light-emitting regions emitting laser beams in a red range; and
among the laser beams emitted from the light-emitting regions, the difference between a peak wavelength in an optical spectrum of at least one laser beam and a peak wavelength in an optical spectrum of the other laser beams is 1.5 nm or more.

The semiconductor laser device in accordance with one embodiment of the present invention is capable of providing a semiconductor laser device that contributes to the improvement of visual sensitivity and image quality.

### BRIEF DESCRIPTION OF DRAWINGS

FIG. 1A is a perspective view illustrating an example of a configuration of a relevant portion of a semiconductor laser device according to one embodiment.

FIG. 1B is a schematic view illustrating a spectral distribution of a laser beam of the semiconductor laser device according to the embodiment.

FIG. 2A is a perspective view illustrating an example of a configuration of a relevant portion of a semiconductor laser device according to another embodiment 1.

FIG. 2B is a cross-sectional view illustrating an example of a configuration of light-emitting layers EL01 to EL04 of a main portion of the semiconductor laser device according to another embodiment 1.

FIG. 2C is a schematic view illustrating a spectral distribution of a laser beam of the semiconductor laser device according to another embodiment 1.

FIG. 3A is a cross-sectional view illustrating an example of a process included in a manufacturing method of a relevant portion of the semiconductor laser device according to another embodiment 1.

FIG. 3B is a cross-sectional view illustrating an example of a process included in the manufacturing method of a relevant portion of the semiconductor laser device according to another embodiment 1.

FIG. 4 is a cross-sectional view illustrating an example of a process included in the manufacturing method of a relevant portion of the semiconductor laser device according to another embodiment 1.

FIG. 5 is a cross-sectional view illustrating an example of a process included in the manufacturing method of a relevant portion of the semiconductor laser device according to another embodiment 1.

FIG. 6 is a cross-sectional view illustrating an example of a process included in the manufacturing method of a relevant portion of the semiconductor laser device according to another embodiment 1.

FIG. 7A is a cross-sectional view illustrating an example of a process included in the manufacturing method of a relevant portion of the semiconductor laser device according to another embodiment 1.

FIG. 7B is a cross-sectional view illustrating an example of a process included in the manufacturing method of a relevant portion of the semiconductor laser device according to another embodiment 1.

FIG. 7C is a cross-sectional view illustrating an example of a process included in the manufacturing method of a relevant portion of the semiconductor laser device according to another embodiment 1.

FIG. 8A is a cross-sectional view illustrating an example of a process included in a modified example 1 of the manufacturing method of a relevant portion of the semiconductor laser device according to another embodiment 1.

FIG. 8B is a cross-sectional view illustrating an example of a process included in a modified example 2 of the manufacturing method of a relevant portion of the semiconductor laser device according to another embodiment 1.

FIG. 9A is a perspective view illustrating an example of a configuration of a relevant portion of a semiconductor laser device according to another embodiment 2.

FIG. 9B is a cross-sectional view illustrating an example of a configuration of light-emitting layers EL11 to EL13 of a relevant portion of the semiconductor laser device according to another embodiment 2.

FIG. 10A is a cross-sectional view illustrating an example of a process included in a manufacturing method of a relevant portion of the semiconductor laser device according to another embodiment 2.

FIG. 10B is a cross-sectional view illustrating an example of a process included in the manufacturing method of a relevant portion of the semiconductor laser device according to another embodiment 2.

FIG. 10C is a cross-sectional view illustrating an example of a process included in the manufacturing method of a relevant portion of the semiconductor laser device according to another embodiment 2.

FIG. 10D is a cross-sectional view illustrating an example of a process included in the manufacturing method of a relevant portion of the semiconductor laser device according to another embodiment 2.

FIG. 11A is a cross-sectional view illustrating an example of a process included in the manufacturing method of a relevant portion of the semiconductor laser device according to another embodiment 2.

FIG. 11B is a cross-sectional view illustrating an example of a process included in the manufacturing method of a relevant portion of the semiconductor laser device according to another embodiment 2.

FIG. 12A is a cross-sectional view illustrating an example of a process included in the manufacturing method of a relevant portion of the semiconductor laser device according to another embodiment 2.

FIG. 12B is a cross-sectional view illustrating an example of a process included in the manufacturing method of a relevant portion of the semiconductor laser device according to another embodiment 2.

FIG. 13A is a cross-sectional view illustrating an example of a process included in the manufacturing method of a relevant portion of the semiconductor laser device according to another embodiment 2.

FIG. 13B is a perspective view illustrating an example of a process included in the manufacturing method of a relevant portion of the semiconductor laser device according to another embodiment 2.

FIG. 14A is a cross-sectional view illustrating an example of a process included in the manufacturing method of a relevant portion of the semiconductor laser device according to another embodiment 2.

FIG. 14B is a perspective view illustrating an example of a process included in the manufacturing method of a relevant portion of the semiconductor laser device according to another embodiment 2.

FIG. 14C is a cross-sectional view illustrating an example of a process included in the manufacturing method of a relevant portion of the semiconductor laser device according to another embodiment 2.

FIG. 14D is a perspective view illustrating an example of a process included in the manufacturing method of a relevant portion of the semiconductor laser device according to another embodiment 2.

FIG. 15 is a graph indicating the relation between the In composition ratio in the quantum well layer QW formed by the selective growth method and the oscillation wavelength.

FIG. 16 is a table indicating the relation between the In composition ratio in the quantum well layer QW formed by the selective growth method and the oscillation wavelength.

FIG. 17 is a graph indicating the amount of strain of Ga_{1-y}In_{y}P with respect to the In composition ratio of the quantum well layer QW.

FIG. 18 is a system schematic diagram of an optical apparatus using a semiconductor laser device according to another embodiment 3.

FIG. 19 is a schematic view illustrating a spectral distribution of a laser beam of the semiconductor laser device according to another embodiment 3.

### DETAILED DESCRIPTION OF THE EMBODIMENTS

The semiconductor laser device according to the present embodiment will be described with reference to the drawings. In the specifications and drawings, the same components or the corresponding components are assigned to the same sign, and duplicate explanations are omitted. In the drawings, some configuration may be omitted or simplified for convenience of explanation. In addition, at least part of each embodiment and each variation may be suitably combined with each other.

It is noted that different signs are assigned to the components when they are necessary to be described individually due to the reason including different their formed locations or the like, for example, the light-emitting sections EM11, EM12, EM13; however, the single sign may be assigned to the component when it is described as a function the component inherently has, for example, the light-emitting section EM.

### [Configuration of the Semiconductor Laser Device According to an Embodiment of the Present Invention]

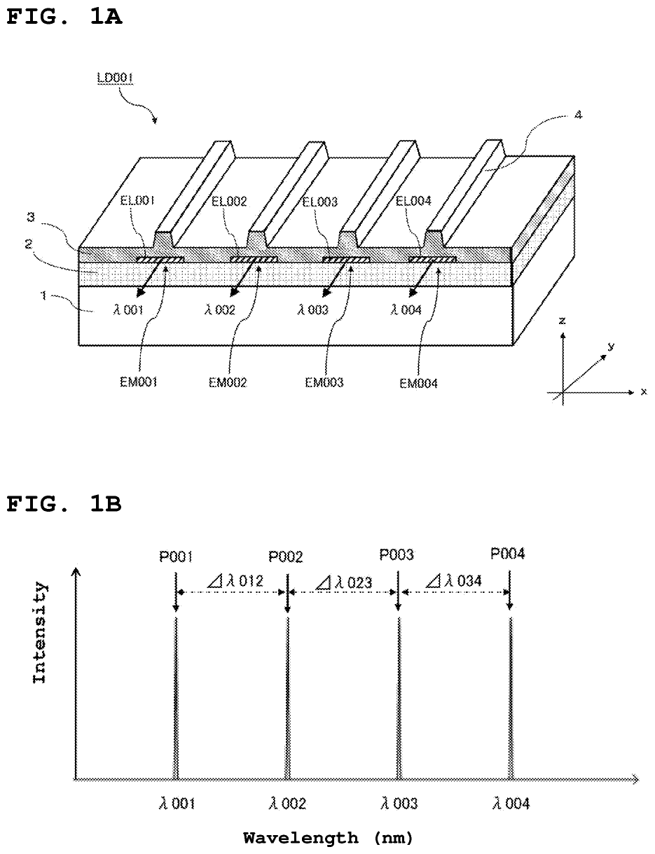

FIG. 1A is a perspective view illustrating an example of a configuration of a relevant portion of a semiconductor laser device according to one embodiment. FIG. 1B is a schematic view illustrating a spectral distribution of a laser beam of the semiconductor laser device according to the embodiment.

For the x-axis, y-axis and z-axis shown in FIG. 1A, x refers to the horizontal direction/width direction/transverse direction, y refers to the depth direction/longitudinal direction, and z refers to the vertical direction/thickness direction/height direction. The definition for these directions also applies to the other figures.

As shown in FIG. 1A, a semiconductor laser device LD001 according to one embodiment includes an n-type cladding layer 2, a light-emitting layer EL and a p-type cladding layer 3 that are formed over a GaAs substrate 1. In addition, four light-emitting sections EM001, EM002, EM003 and EM004 that emit laser beam are formed at predetermined intervals in the x-direction in FIG. 1A.

The light-emitting section EM emits laser beam in the red range (wavelength λ=600 nm to 700 nm). The light-emitting sections EM001, EM002, EM003 and EM004 preferably emit laser beam having wavelengths of λ001 to λ004 respectively, which are different from each other in a range of the red range. It is noted that all of the wavelengths λ of the laser beam emitted from the light-emitting section EM does not have to be different from each other; however, at least one wavelength needs to be different from the others. The wavelength λ shown here refers to the value of the peak wavelength in the optical spectrum of the laser beam emitted from the light-emitting section EM. The same also applies to the other embodiments 1 to 3 shown below.

FIG. 1B shows an exemplary spectral distribution of laser beams emitted from the respective light-emitting sections EM. The peak values P001, P002, P003, P004 of the laser beams emitted from the respective light-emitting sections EM are at λ001=640 nm, λ002=641.5 nm, λ003=643 nm, λ004=644.5 nm, respectively.

In FIG. 1B, the wavelength difference (Δλ012) between the peak wavelength P001 (λ001=640 nm) and the peak wavelength P002 (λ002=641.5 nm) is 1.5 nm. The wavelength difference (Δ×012+Δλ023) between the peak wavelength P001 (λ001=640 nm) and the peak wavelength P003 (λ003=643 nm) is 3 nm. Among the laser beams emitted from the multiple light-emitting sections EM, when at least one of the laser beams has a peak wavelength in the optical spectrum of 1.5 nm or more different from the peak wavelength in the optical spectrum of the other laser beams, this makes it possible to provide good quality images without interference fringes, etc. in imaging devices using the semiconductor laser device.

As a further example, the wavelengths λ of the four laser beams emitted from the light-emitting sections EM are not necessarily different in all of them; λ001 and λ002 may be 640 nm, and λ003 and λ004 may be 641.5 nm. In this way, the difference between the peak wavelength in the optical spectrum of at least one laser beam and the peak wavelength in the optical spectrum of the other laser beams is 1.5 nm or more.

In FIG. 1A, the configuration of the semiconductor laser device with a ridge structure is described; however, the configuration can also be applied to semiconductor laser devices that do not have the ridge structure, such as a semiconductor laser device embedded with a current narrowing layer.

### Another Embodiment 1

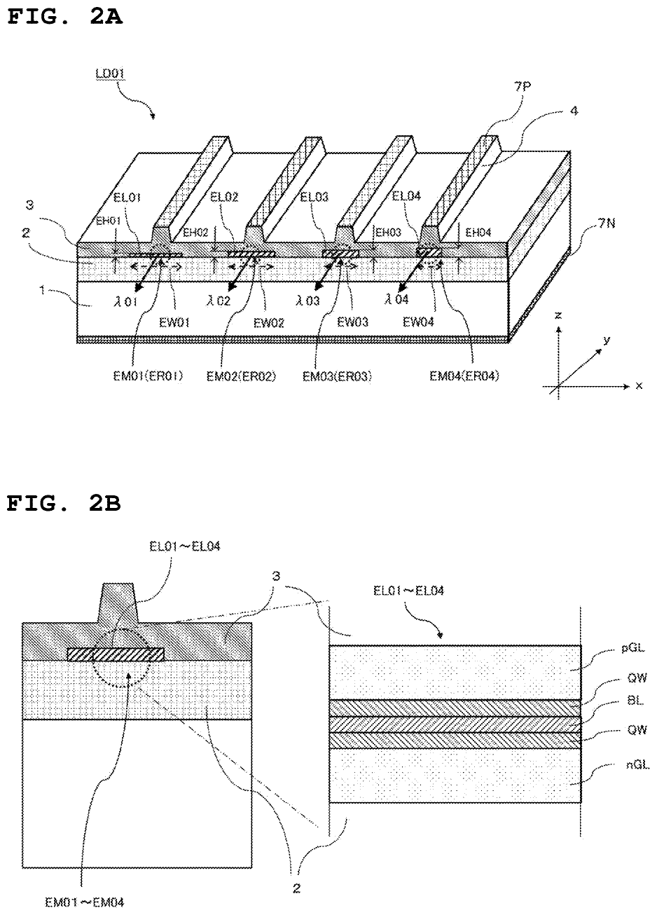

FIG. 2A is a perspective view illustrating a semiconductor laser device LD01 according to another embodiment 1. The semiconductor laser device LD01 includes four light-emitting sections EM01, EM02, EM03 and EM04, which emit laser beams in red range (wavelength λ=600 nm to 700 nm). Among the laser beams emitted from the light-emitting sections EM, at least one of the laser beams preferably has a peak wavelength in the optical spectrum of 1.5 nm or more different from the peak wavelength in the optical spectrum of the other laser beams from the viewpoint of suppressing interference among the laser beams. Also the laser beams preferably have the peak wavelengths in the range that can be perceived as a single color, for example, red. From this viewpoint, the difference in the peak wavelengths is preferably in the range of 30 nm or less.

Each of the light-emitting sections EM01, EM02, EM03 and EM04 has the respective width (EW01, EW02, EW03, EW04) of the light-emitting layers EL, the width being different in size each other. In addition, the light-emitting layers EL01, EL02, EL03 and EL04 have different thicknesses EH of the crystal layers in the respective light-emitting sections EM01, EM02, EM03 and EM04. The light emitting sections EM01, EM02, EM03 and EM04 emit laser beam having different wavelengths λ.

### (Configuration of Semiconductor Laser Device)

FIG. 2A is a perspective view illustrating an example of a configuration of a relevant portion of the semiconductor laser device LD01 according to another embodiment 1. FIG. 2B is a cross-sectional view illustrating an example of a configuration of light-emitting layers EL01 to EL04 of a relevant portion of the semiconductor laser device LD01 according to another embodiment 1. FIG. 2C is a schematic view illustrating a spectral distribution of a laser beam of the semiconductor laser device according to another embodiment 1.

As shown in FIG. 2A, the semiconductor laser device LD01 includes an n-type cladding layer 2 (thickness: 2 μm), light-emitting layers EL01, EL02, EL03, EL04 and a p-type cladding layer 3 (thickness including the top of the ridge: 2 μm) that are formed over a GaAs substrate 1. The light-emitting layers EL01, EL02, EL03 and EL04 are constituted by a crystal layer of ((AlₓGa₁₋ₓ)_{1-y}In_{y}P (0≤x<1, 0<y<1) layers. In addition, the light-emitting layers EL01, EL02, EL03, and EL04 are formed on the same surface of the n-type cladding layer 2. In other words, the bottom surfaces of the light-emitting layers EL01, EL02, EL03 and EL04 are flush in the vertical direction or the thickness direction (corresponding to the z direction in FIG. 2A).

The semiconductor laser device LD01 includes four light-emitting sections EM01, EM02, EM03 and EM04. Each light-emitting section EM has the respective width EW (corresponding to the size in the x direction (horizontal direction) in FIG. 2A) of the light-emitting layers (EL01, EL02, EL03, EL04), the width being different each other. The width EW in accordance with the present embodiment is expressed, from the right side of FIG. 2A, by the relationship EW04<EW03<EW02<EW01. For example, EW04 has a length of 15 μm, EW03 has a length of 25 μm, EW02 has a length of 35 μm, and EW01 has a length of 45 μm. In addition, the light-emitting layers EL01, EL02, EL03 and EL04 have different thicknesses EH of the crystal layers EL01, EL02, EL03 and EL04 (corresponding to the size in the z direction (vertical direction) shown in FIG. 2A). Specifically, the thickness EH of the light-emitting layer EL is expressed, from the left side of FIG. 2A, by the relationship EH01<EH02<EH03<EH04. For example, the light-emitting layer EL01 has a thickness EH01 of 100 nm, the light-emitting layer EL02 has a thickness EH02 of 110 nm, the light-emitting layer EL03 has a thickness EH03 of 120 nm, and the light-emitting layer EL04 has a thickness EH04 of 130 nm.

Each of the light-emitting sections EM01, EM02, EM03, EM04 includes a ridge 4 that is formed by removing a portion of the p-type cladding layer 3 with etching. The ridge serves as a current narrowing structure (current injection structure), and a structure for confining light in the transverse direction (the x direction in FIG. 1A). The p-side electrode 7P is formed on the top face of the ridge 4, and the n-side electrode 7N is formed on the back face of the GaAs substrate 1.

Applying a current between the n-side electrode 7N and p-side electrode 7P causes laser beams (wavelength: 600 nm to 700 nm) in the red range to be emitted from Le light-emitting regions ER01, ER02, ER03, and ER04, which are formed in the four light-emitting sections EM01, EM02, EM03 and EM04, respectively. The laser beams emitted from the light-emitting regions ER have different wavelengths in the respective light-emitting sections EM. Specifically, the wavelength λ is expressed, from the left side in FIG. 2A, by the relationship λ01<λ02<λ03<λ04. For example, laser beams having a wavelength of λ01:640 nm, λ02:641.5 nm, λ03:643 nm, λ04:644.5 nm are emitted. In the present embodiment 1, the multiple laser beams have intervals (Δλ012, Δλ023, Δλ034) of the peak wavelengths in the optical spectrum, the intervals each being set to 1.5 nm; however, the intervals can be appropriately selected in the range from 1.5 nm to 30 nm. In addition, the value of wavelength λ increases as the thickness EH of the light-emitting layer EL increases.

The pitch interval between the center positions of the multiple light-emitting regions ER (or between the center positions of the ridges 4) is selected in the range from 5 μm or more to 100 μm or less. Also, in order to oscillate the red range laser beam (600-700 nm) in the transverse single mode, the ridge width (corresponding to the x direction in FIG. 1A) is necessary to be approximately 2 μm, which satisfies the cutoff condition of the higher-order mode. Therefore, with the consideration of the line and space of the ridges for the multiple beams, it is desirable to determine the minimum pitch interval between the center positions of the multiple light-emitting regions ER (or between the center positions of the ridges 4) to approximately 5 μm. In contrast, in a system in which laser beams are transmitted through a collimating lens and incident on a MEMS mirror to scan the beam for creating an image, the beams with a wide pitch degrades the parallelism of the beams after passing through the collimating lens. Hence, the beams with a wide pitch fail to achieve a constant pixel pitch in the imaging, resulting in lowering image quality. From this viewpoint, the pitch interval is preferably 100 μm or less.

The semiconductor laser device LD01 according to the embodiment 1 can be applied to various end-plane resonant laser devices; for example, it can be applied to a Fabry-Perot laser diode. Note that the laser beam emitted from the light-emitting region of the Fabry-Perot laser diode (LD) has a spectral linewidth between 0.01 nm and 1 nm. Furthermore, in the case of a single mode LD, a spectral linewidth is between 0.05 nm and 0.1 nm, and in the case of a multi-mode LD, a spectral linewidth is approximately 1 nm.

As other examples, it can be applied to a distributed feedback laser diode or a distributed Bragg reflector laser diode. The laser beam emitted from the light-emitting region of these laser diodes has a spectral linewidth between 0.0001 nm and 0.01 nm.

FIG. 2B is a cross-sectional view illustrating an example of a configuration of light-emitting layers EL01 to EL04 of a relevant portion of the semiconductor laser device according to another embodiment 1.

As shown in FIG. 2B, the light-emitting layer EL includes a lower n-side guide layer nGL (several 10 nm), a quantum well layer QW (several nm to several 10 nm), a barrier layer BL (several nm to several 10 nm), a quantum well layer QW (several nm to several 10 nm) and an upper p-side guide layer pGL (several 10 nm). The light-emitting layer EL has a total thickness of approximately 100 nm. The light-emitting regions ER01, ER02, ER03 and ER04, which are illustrated in FIG. 2A, correspond to predetermined regions for the quantum well layer QW. In FIG. 2B, the quantum well layers QW are illustrated as a multiple quantum well layer (MQW); however, it can also be a single quantum well layer (SQW).

Upon the reference to the light-emitting layer EL in the present embodiment, the light-emitting layer EL is defined to be any one of the followings: the light-emitting layer EL includes all of the lower n-side guide layer nGL, the quantum well layer QW, the barrier layer BL and the upper p-side guide layer pGL described above; the light-emitting layer EL includes the quantum well layer QW and the barrier layer BL; or the light-emitting layer EL includes at least part of one of the p-type cladding layer 3 and the n-type cladding layer 2 in addition to the quantum well layer QW and the barrier layer BL.

Next, the explanation is given regarding the fact that a single LD chip emits multiple laser beams with different peak wavelengths in the red range (wavelength λ=600 nm to 700 nm).

FIG. 2C is a schematic view illustrating a spectral distribution of a laser beam of the semiconductor laser device according to the embodiment 1.

As described above, the semiconductor laser device according to the embodiment 1 includes the light-emitting sections EM that emit the laser beams having the peak wavelengths of, for example, 640 nm (λ01), 641.5 nm (λ02), 643 nm (λ03) and 644.5 nm (λ04). Intervals (Δλ012, Δλ023, Δλ034) between the adjacent peak wavelengths in the light spectrum are set to 1.5 nm.

The inventors found, based on their investigation, that laser beam with the expanded full width at half maximum (1.5 nm or more) of the wavelength in its light spectrum improves the image quality. However, red LDs made of AlGaInP-based material have less fluctuation in material composition and layer thickness in the substrate plane than blue and green LDs made of InGaN-based materials. Hence, red LDs has a fluctuation of the peak wavelength of approximately 1 nm in the substrate plane, which is small. In the case of a chip being formed with multiple light-emitting sections, the fluctuation of the peak wavelength is generally 1 nm or less (full width at half maximum of the wavelength in the light spectrum is approximately 0.1 to 1 nm) since the multiple light-emitting sections are closely positioned each other in the chip. This makes it difficult to expand the full width at half maximum to 1.5 nm or more since red range laser beams significantly have a light spectrum with narrow full width at half maximum (approximately 0.01 to 1 nm).

In addition, as described above, the spectral width can be broadened by a wavelength modulation of applying high-frequency superimposition having a pulse width of 15 ns or less to the LD driving current. However, providing a pulse width of 15 ns or less requires a dedicated drive circuit because it is a very short pulse width. In addition, applying high-frequency superimposition to LDs requires the impedance matching to the LDs, thereby the dedicated drive circuit needs to be custom-designed in accordance with the characteristics of the LD elements, significantly increasing the cost. Furthermore, when expanding the spectral width using only high-frequency superimposition, driving a pulse with its pulse width shorter than 15 ns is necessary to expand the full width at half maximum beyond 1.5 nm; however, a drive circuit that accomplishes the high current drive and the short pulse drive is technically challenging and a major constraint in terms of feasibility.

Therefore, the present inventors focus on the fact that radiating multiple laser beams of different peak wavelengths have the effect similar to expanding the full width at half maximum of the wavelength, thus substantially expanding the full width at half maximum of the wavelength.

In this way, the semiconductor laser device of the present embodiment employs the configuration of emitting the multiple laser beams having different peak wavelengths even though its individual laser beam has a small full width at half maximum. Hence, this makes it possible to broaden the spectral width without using a dedicated circuit for high-frequency superimposition. In other words, the configuration of the semiconductor laser device of the present embodiment achieves the effect similar to expanding the full width at half maximum, thus leading to simplifying the overall system configuration. Furthermore, this simplified overall system configuration benefits head mount displays for augmented reality/virtual reality (AR/VR), which are significantly desirable to be compact and light weight since they are worn on a human head. Moreover, employing multiple laser beams having different peak wavelengths in order to broaden the spectral width is more effective in reducing the fringe and improving the image quality.

In the present embodiment 1, the intervals (Δλ012, Δλ023, Δλ034) between the adjacent peak wavelengths of the multiple laser beams is set to 1.5 nm; however, the intervals can be suitably set in the range from 1.5 nm to 30 nm.

As described above, the inventors have found that setting the interval between the adjacent peak wavelengths to at least 1.5 nm enables the effect on reducing the fringes and improving the image quality. In other words, the interval between the adjacent peak wavelengths preferably has a minimum value of 1.5 nm.

In addition, changing the wavelengths of the respective laser beams to ensure a wavelength difference of 3 nm or more between the laser beams further suppresses the interference of the laser beams. This makes it possible to significantly suppress the fringes from occurring in the waveguides and eliminate the effect of the fringes on the images to unnoticed to the human eyes. Also infrared LDs, whose wavelengths are longer than the red region, have low visual sensitivity and cannot be detected by the human eyes, thus no issue of reducing image quality due to fringes caused by wavelengths principally occurs.

The interval between the adjacent peak wavelengths preferably has a maximum value of 30 nm. The reason for this is due to the visibility of red light; the wavelength difference of 30 nm or more lowers the visibility. The visual sensitivity of the human eye peaks at 555 nm and decreases as the wavelength moves away, thereby even when the human looks at light with the same light output, the apparent brightness depends not only on the light output but also on the wavelength.

In the case of red LDs having a wavelength of 600 nm to 700 nm, light having longer wavelength appears darker than that of the same light output since the visual sensitivity lowers with longer wavelength. For example, when the light having a wavelength of 640 nm is compared with the light having a wavelength of 670 nm, which is 30 nm longer than the light having a wavelength of 670 nm, the light having a wavelength of 670 nm has a decreased visual sensitivity of approximately ⅕ to that of the light having a wavelength of 640 nm.

In contrast, red LDs have less light output as the wavelength is shorter because the height of hetero barrier of the bandgap, which is the difference between the band gap of the active layer and the band gap of the cladding layer, cannot be secured. The difference is particularly more prominent in high temperatures, thus light having longer wavelengths are more suitable for higher output. Light having longer wavelengths exhibits lower visual sensitivity; however it has higher light output, compensating the lowering of the visual sensitivity. In general, when the characteristic temperature, which indicates the temperature characteristics of a laser, is considered, 670 nm wavelength light has a superior characteristic temperature than 640 nm wavelength light by a factor of approximately five. Therefore, 670 nm wavelength light is superior to the 640 nm wavelength by a factor of five or more in terms of securing light output at high temperatures, and can also emit five times more light output.

In this way, when the light beams have the wavelength differences of 30 nm or less, the increase in their light output is able to compensate the decrease in the visual sensitivity caused by the longer wavelengths, thereby even 670 nm wavelength light can provide the same visibility as 640 nm wavelength light. Therefore, the light beams having the wavelength differences of 30 nm or less enables respective pixels of the image to have same contrast in the image, suppressing the image quality degradation.

By combining laser beams having multiple wavelengths, the laser beams having the shorter wavelength ensure visual sensitivity, while the laser beams having the longer wavelength ensure high temperature operation. Therefore, combining laser beams having short wavelengths with those having long wavelengths enables both brightness and high temperature operation, which have been specific issues for red LDs.

### (Manufacturing Method of Semiconductor Laser Device)

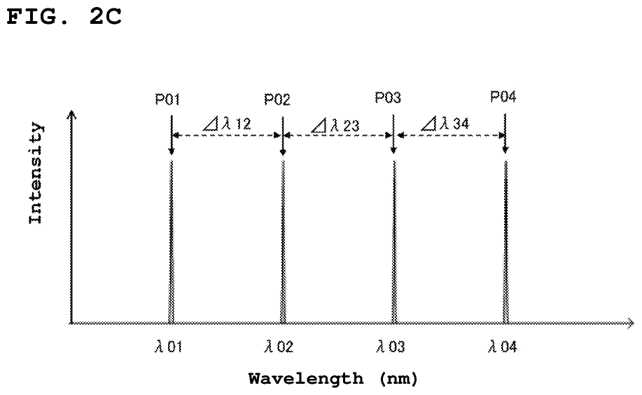

Next, an example of the manufacturing method of the semiconductor laser device LD01 according to the other embodiment 1 will be described. FIGS. 3 to 7 is a cross-sectional view illustrating an example of a process included in a manufacturing method of a relevant portion of the semiconductor laser device LD01.

The manufacturing method of the semiconductor laser device LD01 according to another embodiment 1 mainly includes the steps of:
(1) forming an n-type cladding layer 2 on a GaAs substrate 1;
(2) forming a mask layer MK;
(3) forming light-emitting layers EL01, EL02, EL03 and EL04 by the selective growth method;
(4) forming a p-type cladding layer 3 and a cap layer 5 (including the step of removing the mask layer MK); and
(5) forming ridges and electrodes and then separating into a piece.
   (1) Step of Forming the n-Type Cladding Layer 2 on the GaAs Substrate 1

First, as shown in FIG. 3A, an n-type cladding layer 2 having a thickness of approximately 2 μm is epitaxially grown on the GaAs substrate 1 by MOCVD method. The composition of the n-type cladding layer 2 is expressed by (AlₓGa₁₋ₓ)_{1-y}In_{y}P (0<x≤1, 0<y<1), where x=1 and y=0.5. In the present embodiment, the In composition ratio (y) is adjusted to 0.5 in consideration of the lattice matching with the GaAs substrate 1. The composition ratio of Al and Ga expressed by (x:1−x) preferably has a larger x; thus (x:1−x)=1:0 can also be allowed.

### (2) Step of Forming the Mask Layer MK

Next, as shown in FIG. 3B, after the n-type cladding layer 2 being formed, a silicon oxide (SiO₂) film is formed on the surface of the n-type cladding layer 2 with CVD method, the silicon oxide (SiO₂) film functioning as a mask layer MK. The SiO₂ film serves to inhibit crystal growth; silicon nitride (Si₃N₄) film, for example, can also be used.

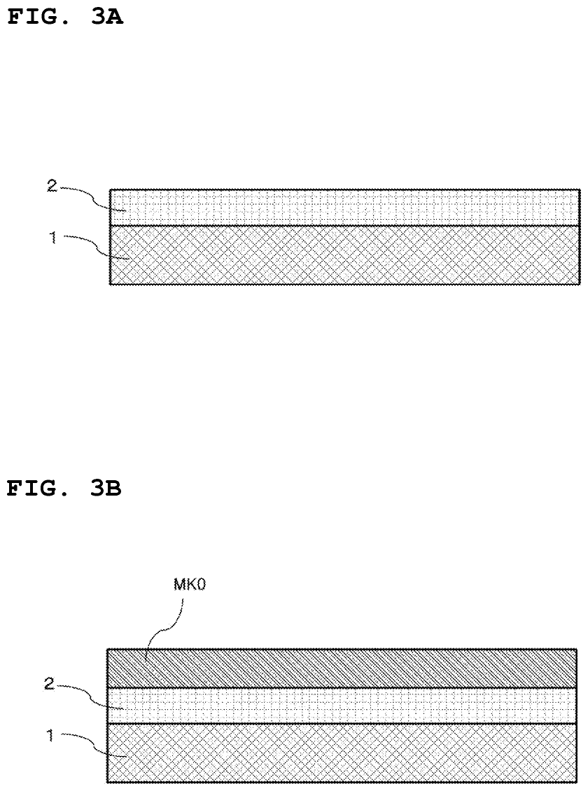

After the SiO₂ film being formed, multiple striped-patterned openings (four openings in the present embodiment) are formed in the SiO₂ film using the lithography method, as shown in FIG. 4. The four openings each have different widths (corresponding to the length in the x-direction (horizontal direction) shown in FIG. 2A); the widths are formed so as to become narrower in order from the left side in FIG. 4. In other words, the mask layers MK01 to MK05 are formed to allow the widths to satisfy EW04<EW03<EW02<EW01 (see FIG. 2A).

### (3) Step of Forming the Light-Emitting Layers EL01, EL02, EL03 and EL04 by Selective Growth Method

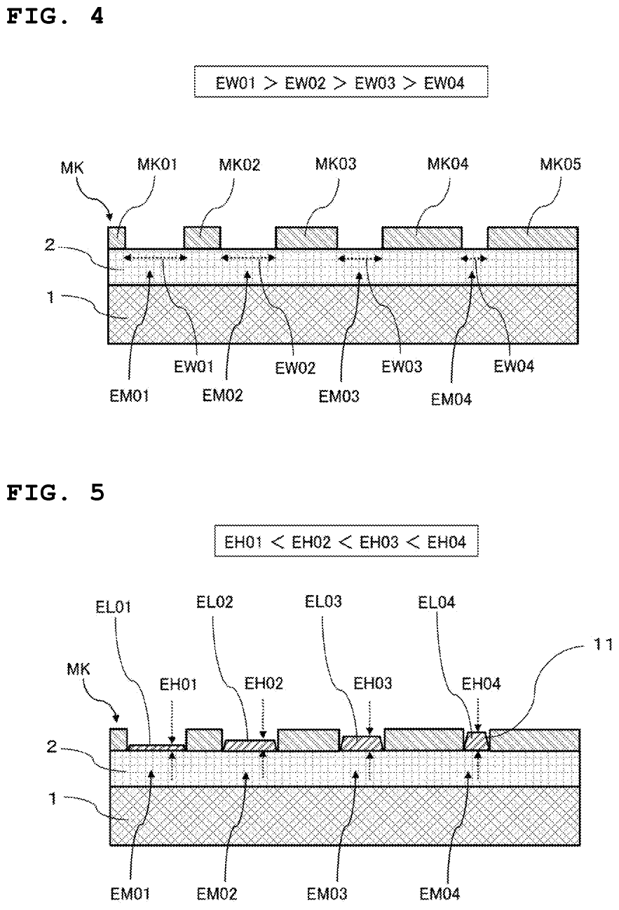

Next, as shown in FIG. 5, the light-emitting layers EL01, EL02, EL03 and EL04, each of which is composed of the lower n-side guide layer nGL, quantum well layer QW, barrier layer BL and upper p-side guide layer pGL, are formed on the regions through the openings of the mask layer MK. These layers are formed by using a method called selective growth. The selective growth method utilizes the fact that crystals are not deposited on the top face of the mask layer MK, thereby forming a desired layer only on the regions through the openings of the mask layer MK.

The crystal grown by the selective growth method is (AlₓGa₁₋ₓ)_{1-y}In_{y}P (0≤x<1, 0<y<1). The raw material gases used include trimethylaluminum (TMA), trimethylgallium (TMG) and trimethylindium (TMI).

By the selective growth method, deposited are the lower n-side guide layer nGL, the quantum well layer QW, the barrier layer BL, the quantum well layer QW and the upper p-side guide layer pGL in sequence on the region through the openings of the mask layer MK as shown in FIG. 2B. For example, the lower n-side guide layer nGL and the upper p-side guide layer pGL are composed of (AlₓGa₁₋ₓ)_{1-y}In_{y}P, where the composition ratio is x=0.7 and y=0.5, each layer having a thickness of 50 nm to 60 nm. The quantum well layer QW is composed of GaInP and has a thickness of 5 nm to 6 nm. The barrier layer is composed of (AlₓGa₁₋ₓ)_{1-y}In_{y}P, where the composition ratio is x=0.7 and y=0.5 and has a thickness of 5 nm to 6 nm. The light-emitting layer EL01 is formed in the region having the widest opening (EW01) of the mask layer MK, and the light-emitting layer EL04 is formed in the region having the narrowest opening (EW04). When the light-emitting layer EL is formed by the selective growth method, the light-emitting layer EL has inclined side faces 11. In other words, the light-emitting layer EL has the side faces extending in the longitudinal direction of the ridge (corresponding to the y-direction in FIG. 2A); and the side faces incline inward as the thickness of the light-emitting layer EL increases.

The step of forming the light-emitting layer EL includes forming (AlₓGa₁₋ₓ)_{1-y}In_{y}P by the selective growth method. The values of x and y, which indicate the composition ratio of elements, are determined on the followings.

The guide layer GL may be referred to a separated confinement hetero-structure (SCH) layer or a confinement layer, and preferably has a higher refractive index than the cladding layer 2 (3) and a lower refractive index than the quantum well layer QW. Hence, the feed ratio of the raw material is adjusted such that the Al composition ratio (x) of the guide layer GL becomes smaller than that of the cladding layer 2 (3). For example, the feed amount of the raw material is adjusted such that the Al composition ratio (x) is highest in the cladding layer 2 (3), and lowers in the order of the guide layer GL, the barrier layer BL and the quantum well layer QW.

In the present embodiment, the composition ratio of the guide layer GL and the barrier layer BL is determined to be x=0.7 and y=0.5. In the growth of the quantum well layer QW, TMA of the raw material gas is not fed, thus the quantum well layer QW is made of GaInP, which contain no Al (i.e., x=0). The quantum well layer QW has a thickness in the range of 5 nm to 6 nm.

The light-emitting layer EL formed by the selective growth method functions as a core layer in the optical waveguide. The thickness of the light-emitting layer EL, which is dependent on the wavelength of each laser beam and the refractive index of each layer, is selected in the range between approximately 50 nm and approximately 500 nm for a red laser; in the present embodiment, the thickness thereof is approximately 100 nm in total.

Each of the light-emitting layers EL formed by the selective growth method has the different thickness EH. In other words, the size of the openings of the mask layer MK causes the thickness of the light-emitting layer EL to vary during the selective growth, making the thickness of the light-emitting layer EL thicker as the widths of the light-emitting layer EL is narrower. Specifically, the thickness EH is expressed by, from the left side in FIG. 5, the relationship EH01<EH02<EH03<EH04.

As described above, depositing the light-emitting layer EL by the selective growth method on the region through the openings of the mask layer MK, which are different in size, causes the thickness of the light-emitting layer EL to vary. The mechanism is not clearly understood; however, it is inferred as described in the following (i)-(iv).

(i) In the selective growth method, layer growth does not occur on the surface of the mask layer MK; thereby the raw material gas fed to the surface of the mask layer MK migrates on the surface of the mask layer MK and moves to the region of the openings of the mask layer MK.

(ii) The amount of the migrating raw material gas increases as the surface area of the mask layer MK is larger.

(iii) A larger amount of raw material gas migrates to the region of the openings of the mask layer MK adjacent to the mask layer MK having a larger surface area, thus the concentration of the raw material gas in the openings becomes high. Furthermore, if the opening of the mask layer MK is smaller, the concentration of the raw material gas will be higher.

(iv) As a result, more raw materials are fed to the light-emitting layer EL04, which is formed on the region through the narrowest opening of the mask layer MK.

(4) Step of Forming the p-Type Cladding Layer 3 and the Cap Layer 5 (Including the Step of Removing the Mask Layer MK)

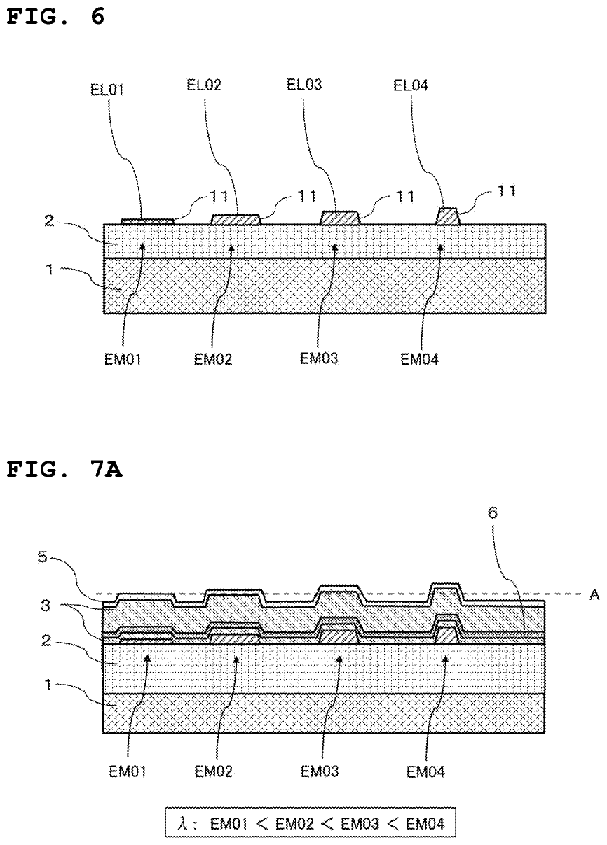

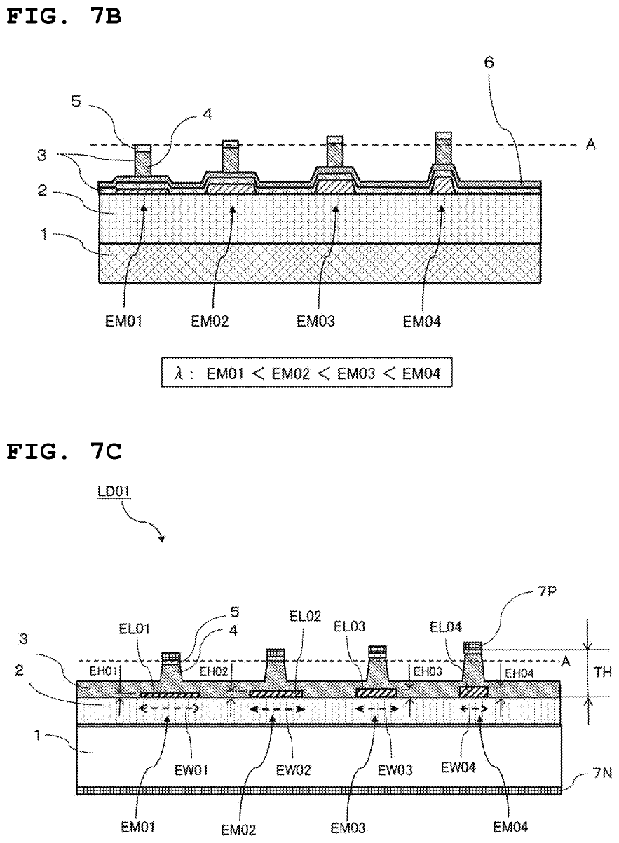

Next, as shown in FIG. 6, the mask layer MK is removed. Then, as shown in FIG. 7A, the p-type cladding layer 3 having a thickness of approximately 2 μm is epitaxially grown by the MOCVD method, and followed by forming the cap layer 5 having a thickness of 0.5 μm. In addition, the step of forming an etch stop layer 6 is included in the step of forming the p-type cladding layer 3. The etch stop layer 6 functions as a layer of stopping etching when etching the p-type cladding layer 3 to form the ridge 4 in the next step (5). As examples of each layer, the p-type cladding layer 3 is composed of AlInP and has a thickness of 2 μm. The etch stop layer 6 is composed of GaInP and has a thickness of 2 nm.

(5) Step of Forming Ridges and Electrodes and then Separating into a Piece

Next, as shown in FIG. 7B, the p-type cladding layer 3 is etched into a predetermined shape to form ridges 4 for the respective light-emitting layers EL01, EL02, EL03 and EL04. In FIG. 7B, the thickness from the top face of the cladding layer 2 to the top faces of the ridges 4 (edges of the side of the p-side electrodes 7P) is illustrated in an exaggerated manner; however, thickness of the ridges 4 (distance in the thickness direction) formed with the etching is, for example, approximately 1 μm. Then, a passivation oxide film (not shown) such as SiO₂ is formed, and openings in the oxide film are provided at the top face of the ridge using photolithography and etching techniques, forming the p-type electrodes 7P on the openings. FIG. 7C is a cross-sectional view schematically illustrating the semiconductor laser device LD01 that has been formed with the electrodes. This shape corresponds to the semiconductor laser LD01 shown in FIG. 2A as a perspective view. The GaAs substrate is then cleaved and the cleaved surface is performed with an edge coating to form the semiconductor laser LD01 shown in FIG. 2A.

In this way, the layer deposited by the selective growth method in accordance with the present embodiment 1 is the light-emitting layer EL, which is a relatively thin layer and formed in the step (3). In contrast, the n-type cladding layer 2 and the p-type cladding layer 3, which are formed in the step (1) and the step (4), are formed without using the selective growth method.

Here, the thickest light-emitting layer EL04 is approximately 1.2 to 1.3 times as thick as the thinnest light-emitting layer EL01. This corresponds to a difference in thickness of approximately 20 to 30 nm, which is a negligible thickness compared with the total thickness (several micrometers (several thousand nanometers)) including the GaAs substrate 1. When a thickness from the bottom face of the n-type cladding layer 2 to the top face of the cap layer 5 is, for example, 4 to 5 μm (4000 to 5000 nm), the difference in thickness (20 to 30 nm) between the thickest light-emitting layer EL04 and the thinnest light-emitting layer EL01 is less than 1% of the thickness. FIG. 7C also shows a thickness TH corresponding to a thickness from the top face of the n-type cladding layer 2 to the top face of the cap layer 5. Therefore, forming only the light-emitting layers EL by the selective growth method suppresses the difference in the height of each of the light-emitting sections EM.

In this way, the value of the peak wavelength in the optical spectrum of the laser beam varies in accordance with the thickness of the light-emitting layers EL01, EL02, EL03 and EL04 formed on the same surface. In addition, since only the light-emitting layer EL is formed by the selective growth method in the manufacturing process of the semiconductor laser device (the n-type cladding layer and p-type cladding layer are not formed by the selective growth method), the level difference with respect to the overall chip height is reduced. In this way, performing separately the crystal growth three times to the layers (n-type cladding layer, light-emitting layer EL and p-type cladding layer) allows the n-type cladding layer and the p-type cladding layer (thickness for both layers: approximately 4 μm) to have no difference in thickness, exhibiting the difference in thickness only in the light-emitting layer (about 100 nm), which is formed relatively thin. Hence, this makes it possible to suppress the difference in height of the beam position from which the light-emitting section EM emits the beam. Furthermore, this configuration achieves uniform solder wettability during the J-down mounting and prevents the chips from tilting, thereby eliminating defects.

### Advantage of the Embodiment 1

The four light-emitting sections EM01, EM02, EM03 and EM04 emit laser beams having different peak wavelengths in a predetermined range in the optical spectrum. This configuration makes it possible to suppress the image quality degradation due to the interference of laser beam, further improving visual sensitivity and image quality such as a wide color gamut, high resolution and a wide viewing angle. Accordingly, the embodiment 1 provides a semiconductor laser device that contributes to improve the visibility and the image quality.

### Modified Example 1

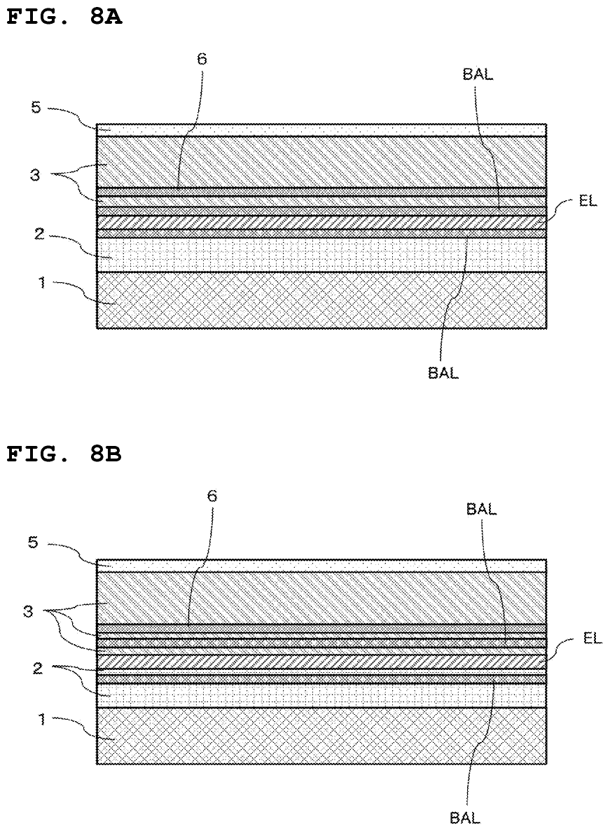

A modified example 1 of the manufacturing method for the semiconductor laser device LD01 according to another embodiment 1 will be described. FIG. 8A is a cross-sectional view illustrating an example of a process included in a modified example 1 of the manufacturing method of a relevant portion of the semiconductor laser device according to another embodiment 1.

As shown in FIG. 8A, the modified example 1 of another embodiment includes a buffer layer BAL (or re-growth interface layer) immediately after the step (1) and the step (3). In other words, the buffer layer BAL (3 nm thickness) is formed on the surface of the n-type cladding layer 2 and the surface of the light-emitting layer EL.

As described above, the laser device of the red range is constituted by a crystal layer of (AlₓGa₁₋ₓ)_{1-y}In_{y}P, which contains Al; however, Al is highly susceptible to be oxidized. Hence, the buffer layer BAL is formed as an oxidation prevention layer to prevent the oxidation of the crystal growth interface between the processes. The oxidation of Al causes an increase in the rate of non-light-emitting recombination of carriers, leading to performance degradation such as a decrease in the light-emitting efficiency, which in undesirable. The buffer layer BAL uses a material selected from materials containing no Al or having a low mixed ratio of Al; for example, GaInP or GaAs is selected. When GaAs is selected as a material for the buffer layer BAL, the buffer layer may be removed by etching immediately before the subsequent step after the step of having formed the buffer layer BAL. As long as GaAs serves to suppress the oxidation of Al between the processes, GaAs is not necessarily present in the finished product, because it absorbs light.

### Modified Example 2

A modified example 2 of the manufacturing method for the semiconductor laser device LD01 according to another embodiment 1 will be described. FIG. 8B is a cross-sectional view illustrating an example of a process included in a modified example 2 of the manufacturing method of a relevant portion of the semiconductor laser device according to another embodiment 1.

In the modified example 2 of another embodiment 1, the buffer layer BAL is formed in the middle of the step (1) and the step (4) as shown in FIG. 8B. In other words, the buffer layer BAL is formed after partially forming the n-type cladding layer 2; the mask layer MK is formed thereon, then the remaining n-type cladding layer 2, the light-emitting layer EL, a part of the p-type cladding layer 3 and the buffer layer BAL are grown in sequence by the selective growth method. After the step of removing the mask layer MK, the remaining p-type cladding layer 3 and the cap layer 5 are grown in sequence. The p-type cladding layer 3 may include the etch stop layer 6. Through these steps, the buffer layers BAL are formed inside the n-type cladding layer 2 and the p-type cladding layer 3 at a predetermined distance from the interface of the light-emitting layer EL. In this way, providing the buffer layer BAL at a predetermined distance from the interface of the light-emitting layer EL enables the reduction of the light absorption and the adjustment of the refractive index distribution.

The modified examples 1 and 2 described above are also applicable to another embodiment 2 that will be described below.

### Another Embodiment 2

The semiconductor laser device LD1 according to another embodiment 2 includes three light-emitting sections EM11, EM12 and EM13, which emit laser beams having the red range (wavelength λ: 600 nm to 700 nm). Among the laser beams emitted from the multiple light-emitting sections EM, the difference between the peak wavelength in the optical spectrum of at least one laser beam and the peak wavelength in the optical spectrum of the other laser beams is in a range from 1.5 nm to 30 nm.

Each of the light-emitting sections EM11, EM12, EM13 has a different width (EW11, EW12, EW13) and emits laser beam having a different wavelength. In addition, each of the light-emitting sections EM11, EM12, EM13 includes the light-emitting layers (EL11, EL12, EL13), each of the light-emitting layers (EL11, EL12, EL13) has a different thickness EH, and a different composition ratio in the crystal layer of the light-emitting layer.

The semiconductor laser device LD1 according to another embodiment 2 has the same configuration of the semiconductor laser device LD01 according to another embodiment 1 except the fact that each of the light-emitting sections EM11, EM12, EM13 has a different composition ratio in the crystal layer thereof. Thus, unless otherwise mentioned, the following description will focus on the points that differ from those of another embodiment 1, and the repetition of the same description will be omitted. In another embodiment 2, it is noted that the configuration is opposite to that of another embodiment 1 with respect to the left and right sides, also the numbers of the light-emitting layers and the etch-stop layers 6, which are shown in another embodiment 1, are omitted from the configuration for convenience of explanation.

For the red range laser beam, Al (aluminum) and In (indium) are doped in the crystal layer of the semiconductor laser device, as described in detail below. The semiconductor laser device according to embodiment 2 is capable of emitting multiple laser beams having different wavelengths from a single chip by particularly varying the composition ratio of In (indium) among the compositions constituting the crystal layers.

### (Configuration of the Semiconductor Laser Device)

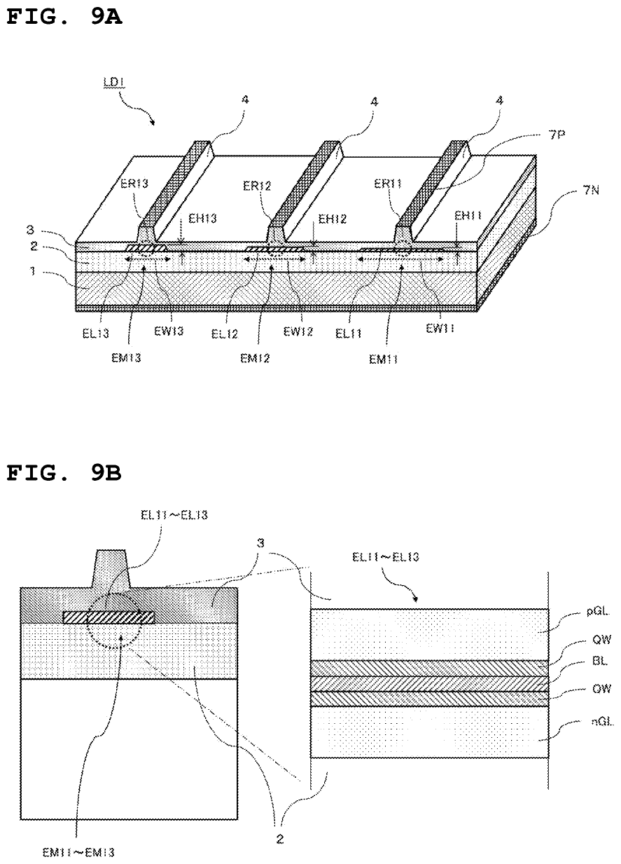

FIG. 9A is a perspective view illustrating an example of a configuration of a relevant portion of a semiconductor laser device according to another embodiment 2. FIG. 9B is a cross-sectional view illustrating an example of a configuration of light-emitting layers EL11 to EL13 of a relevant portion of the semiconductor laser device according to another embodiment 2.

As shown in FIG. 9A, the semiconductor laser device LD1 includes the n-type cladding layer 2, the light-emitting layer EL11, EL12, EL13 and the p-type cladding layer 3 over the GaAs substrate 1. In addition, the semiconductor laser device LD1 includes the three light-emitting sections EM11, EM12, EM13, each of the light-emitting sections has the light-emitting layer having a different width (corresponding to the length in the x direction (horizontal direction) shown in FIG. 1A). In other words, the width is expressed by the relationship EW13<EW12<EW11. Moreover, the light-emitting layers EL have different thicknesses EH similar to that of another embodiment 1; however, unless otherwise mentioned, the explanation of the thickness will be omitted in another embodiment 2. It is noted that the height EH is expressed by the relationship EH11<EH12<EH13. Moreover, the light-emitting layers include slopes 11 at their edges on the top thereof, which is similar to that of embodiment 1; however, they are omitted in another embodiment 2.

Each of the light-emitting sections EM01, EM02, EM03 includes a ridge 4 that acts as a current narrowing structure (current injection structure) that has been formed by removing a portion of the p-type cladding layer 3 with etching, and also acts as a structure for confining light in the transverse direction (the x direction in FIG. 9A). In addition, the n-type electrode 7N is formed on the back surface of the GaAs substrate 1 and the p-type electrodes 7P are formed on the top faces of the ridges 4.

Applying a current between the p-type electrodes 7P and the n-type electrodes 7N allows the light-emitting regions ER11, ER12, ER13 formed in the three light-emitting sections EM11, EM12, EM13 respectively, to emit laser beams having the red range (wavelength: 600 nm to 700 nm). The wavelength λ of the laser beams emitted is expressed by the relationship EM13>EM12>EM11. As an example, the light-emitting region ER11 emits the laser beam having a wavelength of 654 nm, ER12 of 658 nm, and ER13 of 662 nm, respectively.

In the example described above, every adjacent wavelength is set to have a difference of 4 nm; however, the wavelength difference can be set in the range of 1.5 nm to 30 nm. For example, when the wavelength difference is set to 1.5 nm, the light-emitting region ER11 emits the laser beam having a wavelength of 620 nm, ER12 of 621.5 nm, and ER13 of 623 nm, respectively. In addition, when the wavelength difference is set to 30 nm, the light-emitting region ER11 emits the laser beam having a wavelength of 630 nm, ER12 of 660 nm, and ER13 of 690 nm, respectively.

The light-emitting layers EL11, EL12, EL13 are constituted by the crystal layer of (AlₓGa₁₋ₓ)_{1-y}In_{y}P (0≤x<1, 0<y<1), each of the light-emitting layers EL includes the crystal layer having a different In composition ratio (y). As an example, the In composition ratio (y) of the light-emitting layer EL11 is 0.51, the In composition ratio (y) of the light-emitting layer EL12 is 0.55, and the In composition ratio (y) of the light-emitting layer EL13 is 0.59. The In composition ratio (y) is preferably selected from a range of 0.35 to 0.65, the detail of which will be described later. As the detail will be described later, the light-emitting layers EL are constituted by multiple layers; the quantum well layer QW has a smallest Al composition ratio (x). It is noted that an indirect transition occurs when the Al composition ratio (x) exceeds approximately 0.5, thus the Al composition ratio (x) of the quantum well layer QW is 0.5 or less.

An exemplary configuration of the light-emitting layer EL11, EL12, EL13 will be described in FIG. 9B. The light-emitting layers EL includes the lower n-side guide layer nGL (several tens of nm), the quantum well layers QW (several nm to several tens of nm), the barrier layer BL (several nm to several tens of nm) and the upper p-side guide layer pGL (several tens of nm), and have a total thickness of approximately 100 nm as shown in FIG. 9B. The light-emitting regions ER11, ER12, ER13 shown in FIG. 9A correspond to the intended regions for the quantum well layers QW. The quantum well layers QW shown in FIG. 9B are illustrated as a single quantum well layer (SQW); however, it can be a multiple quantum well layer (MQW).

It is noted that upon the reference to the light-emitting layer EL of the present embodiment, the light-emitting layer EL is defined to be any one of the followings: the light-emitting layer includes all of the lower n-side guide layer nGL, the quantum well layers QW, the barrier layer BL and the upper p-side guide layer pGL, which are described above; the light-emitting layer EL includes the quantum well layers QW and the barrier layer BL; or the light-emitting layer EL includes part of the p-type cladding layer 3 in addition to the quantum well layers QW and the barrier layer BL.

### (Method of Manufacturing the Semiconductor Laser Device)

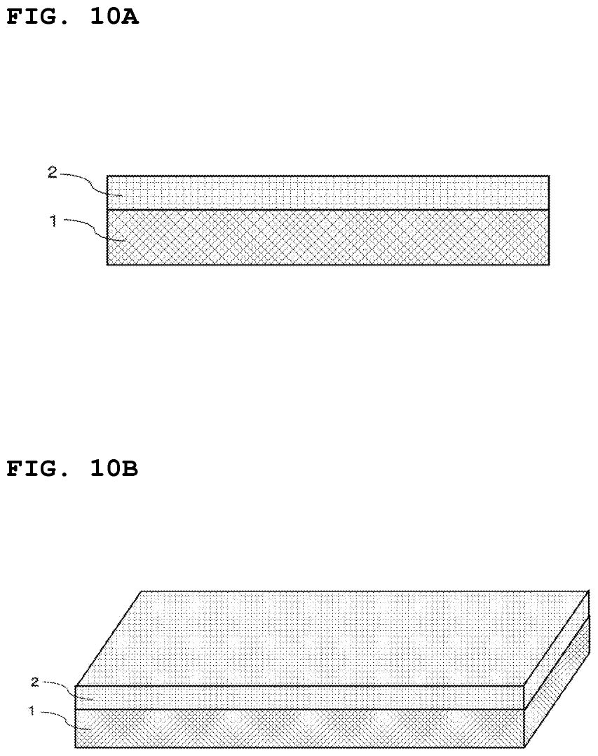

An exemplary method of manufacturing the semiconductor laser device LD1 according to another embodiment 2 will be described. FIGS. 10 to 14 are views illustrating an exemplary process included in a method of manufacturing the semiconductor laser device LD1. FIGS. 10A to 14A are cross-sectional views illustrating an exemplary process included in the method of manufacturing the semiconductor laser device according to another embodiment 2. FIGS. 10B to 14B are perspective views illustrating an exemplary process included in the method of manufacturing the semiconductor laser device according to another embodiment 2.

The method of manufacturing the semiconductor laser device LD1 according to another embodiment 2 mainly includes the step of (1) forming the n-type cladding layer 2 on the GaAs substrate 1, (2) forming the mask layer MK, (3) forming the light-emitting layer EL11, EL12, EL13 by the selective growth method, (4) forming the p-type cladding layer 3 and the cap layer 5 (including a process of removing the mask layer MK), (5) forming ridges and electrodes and then separating into a piece.

(1) Step of Forming the n-Type Cladding Layer 2 on the GaAs Substrate 1

First, as shown in FIGS. 10A and 10B, the n-type cladding layer 2 having a thickness of approximately 2 μm is epitaxially grown on a GaAs substrate 1 by the MOCVD method. The composition of the n-type cladding layer 2 is expressed by (AlₓGa₁₋ₓ)_{1-y}In_{y}P (0<x≤1, 0<y<1), where x=1 and y=0.5. The In composition ratio (y) of the present embodiment is adjusted to 0.5 with consideration of the lattice matching with GaAs substrate 1. The composition ratio of Al and Ga expressed by (x:1−x) preferably has a larger x; thus (x:1−x)=1:0 can also be allowed.

### (2) Step of Forming the Mask Layer MK

Next, as shown in FIGS. 10C and 10D, after forming the n-type cladding layer 2, a silicon oxide (SiO₂) film that functions as a mask layer MK is formed on the surface of the n-type cladding layer 2 by the CVD method. The SiO₂ film serves to inhibit crystal growth; silicon nitride (Si₃N₄) film, for example, can also be used.

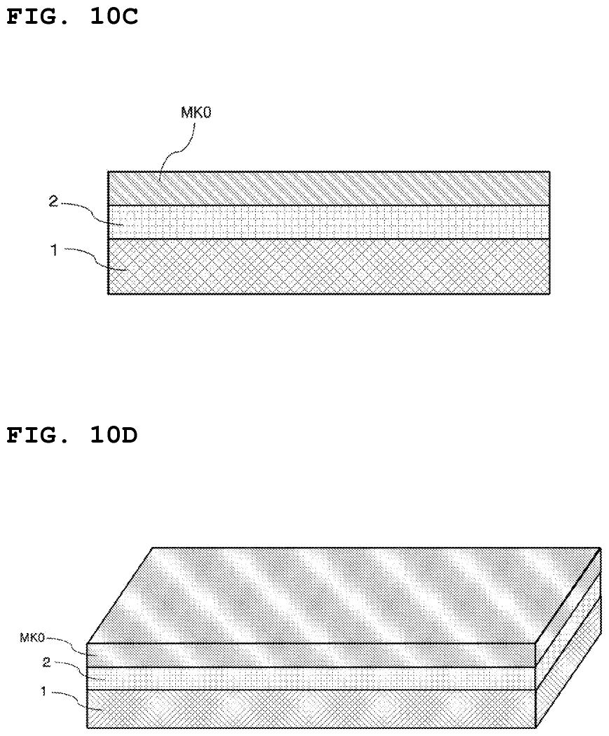

After forming the SiO₂ film, multiple stripe-shaped openings (three openings in the present embodiment) are formed in the SiO₂ film by the lithography method, as shown in FIGS. 11A and 11B. The three openings have different widths (corresponding to the size in the x direction (horizontal direction) shown in FIG. 9A), and are formed such that the width of each opening becomes wider in order from the left side in FIGS. 11A and 11B. In other words, the width is formed so as to satisfy the relationship EW13<EW12<EW11. Each of the widths of the three openings (corresponding to the size in the x direction (horizontal direction) shown in FIG. 9A) is narrower in order from the left side of FIGS. 11A and 11B. The widths of the openings of the mask layer are, for example, MK4: 50 μm, MK3: 35 μm, MK2: 30 μm and MK1: 15 μm.

### (3) Step of Forming the Light-Emitting Layer EL11, EL12, EL13 by the Selective Growth Method

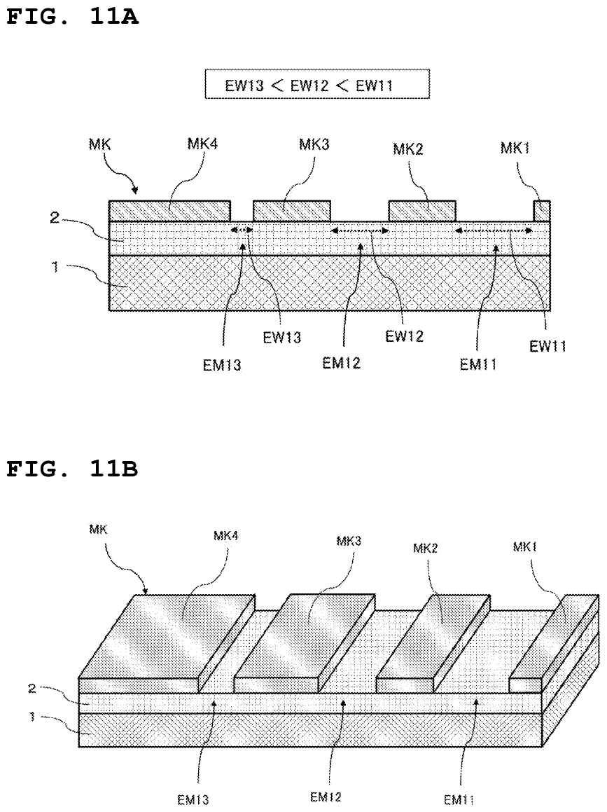

Next, as shown in FIGS. 12A and 12B, the light-emitting layers EL11, EL12 and EL13, which consist of the lower n-side guide layer nGL, the quantum well layer QW, the barrier layer BL and upper p-side guide layer pGL, are formed on the region through the openings of the mask layer MK. These layers are formed by the selective growth method. The selective growth method uses the fact that crystals are not deposited on the top face of the mask layer MK to form the desired layer only on the region through the openings of the mask layer MK.

The crystals grown by the selective growth method is (AlₓGa₁₋ₓ)_{1-y}In_{y}P (0≤x<1, 0<y<1). The raw material gases used include trimethylaluminum (TMA), trimethylgallium (TMG) and trimethylindium (TMI).

By the selective growth method, deposited are the lower n-side guide layer nGL, the quantum well layer QW, the barrier layer BL, the quantum well layer QW and the upper p-side guide layer pGL in sequence on the regions through the openings of the mask layer MK. The light-emitting layer EL11 is formed in the region having the widest opening (EW11) of the mask layer MK, and the light-emitting layer EL13 is formed in the region having the narrowest opening (EW13). The light-emitting layer EL12 is formed in the region having the intermediate opening (EW12) of the mask layer MK.

The step of forming the light-emitting layers EL uses the selective growth method to form (AlₓGa₁₋ₓ)_{1-y}In_{y}P; the values of x and y representing the composition ratio of elements are determined on the followings.

The guide layer GL is referred to a SCH (Separated Confinement Heterostructure) layer or a confinement layer, and preferably has a higher refractive index than the cladding layer 2(3) and a lower refractive index than the quantum well layer QW. Hence, the feed ratio of the raw material is adjusted to make the Al composition ratio (x) lower compared to that of the cladding layer 2 (3). For example, the feed amount of the raw material gas is adjusted such that the Al composition ratio (x) is highest in the cladding layer 2 (3), and becomes lower in the guide layer GL or the barrier layer BL, and the quantity well layer QW in that order.

According to the present embodiment, the guide layers GL and the barrier layers BL are constituted by the composition of (AlₓGa₁₋ₓ)_{1-y}In_{y}P, where the composition ratio is x=0.7 and y=0.5, and have a thickness of, for example, 50 nm to 60 nm. TMA as a raw material is not supplied for growing the quantum well layer QW, thus the quantum well layer QW contains no Al (i.e., x=0) and has the composition of GaInP. The quantum well layer QW has a thickness of 5 nm to 6 nm.

The light-emitting layer EL formed by the selective growth method functions as a core layer of an optical waveguide. In a laser beam in red range, the thickness of the light-emitting layer EL is selected in the range of approximately 50 nm and 500 nm although depending on the wavelength of the laser and the refractive indexes of the respective layers; the light-emitting layer EL of the present embodiment has a total thickness of approximately 100 nm.

In the step of forming the light-emitting layer EL, the growth rate by the selective growth method is set to be higher than the normal rate. For example, in the case in which the normal growth rate is 1 to 2 μm/h, the growth rate according to the present embodiment is increased approximately by 20 to 80 percent by increasing the feed amount of the raw material gas. Increasing the growth rate enables the In composition in the light-emitting layer EL11, EL12, El13 to be controlled. Specifically, the In composition ratio is highest in the light-emitting layer EL13, which is formed on the region through the narrowest opening (EW13) in the mask layer MK; and the In composition ratio becomes lower in the light-emitting layer EL12 and the light-emitting layer EL11 in order. In this way, the condition that higher In composition ratio is deposited on the region through the stripe having the narrower opening in the mask layer MK is used.

The mechanism of controlling the In composition in each of the light-emitting layers EL11, EL12, EL13 is not clearly understood; however, it is inferred as described in the following (i)-(iv).

(i) In the selective growth method, layer growth does not occur on the surface of the mask layer MK; thereby the raw material gas fed to the surface of the mask layer MK migrates on the surface of the mask layer MK and moves to the region of the openings of the mask layer MK.

(ii) The amount of the migrating raw material gas increases as the surface area of the mask layer MK is larger.

(iii) A larger amount of raw material gas migrates to the region of the openings of the mask layer MK adjacent to the mask layer MK having a larger surface area, thus the concentration of the raw material gas in the openings becomes high. Furthermore, if the opening of the mask layer MK is smaller, the concentration of the raw material gas will be higher.

(iv) As a result, higher In (indium) is incorporated into the light-emitting layer EL13, which is formed on the region through the narrowest opening of the mask layer MK. In this way, the composition ratio on the region through each opening is adjusted by facilitating the diffusion of the raw material gas in the lateral direction on the surface of the mask layer MK, and by especially using the phenomenon that the region through the narrower opening has the higher composition of the raw material (for example, TMI including In) that tends to be influenced by diffusion in the lateral direction.

The thickness of the light-emitting layer EL is expressed by the relationship EL11<EL12<EL13.

(4) Step of Forming the p-Type Cladding Layer 3 and the Cap Layer 5 (Including the Step of Removing the Mask Layer MK)

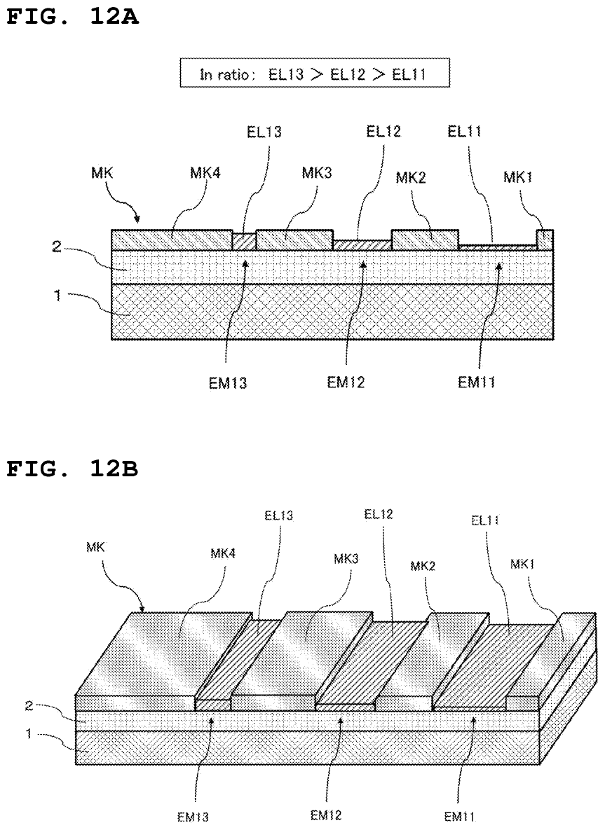

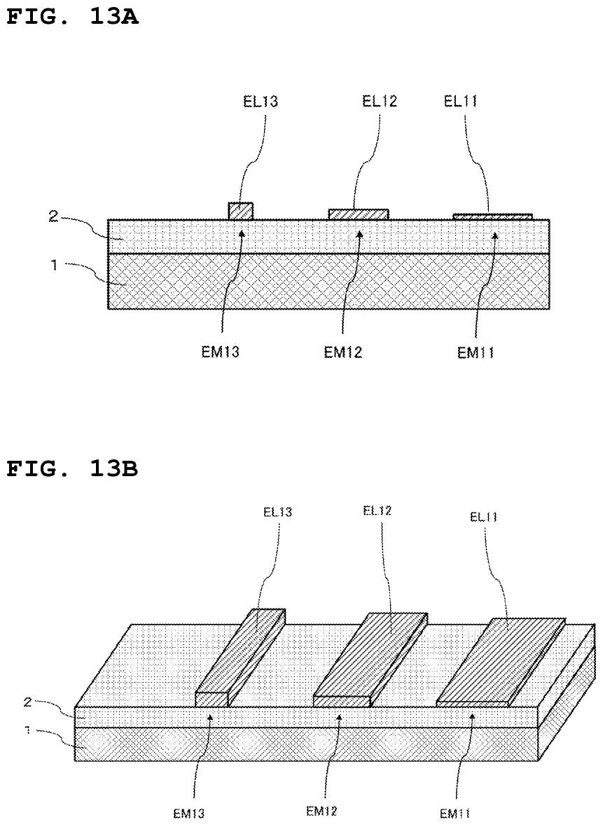

Next, the mask layer MK is removed as shown in FIGS. 13A and 13B. The p-type cladding layer 3 having a thickness of approximately 2 μm is epitaxially grown by the MOCVD method, and followed by forming the cap layer 5 having a thickness of 0.5 μm as shown in FIGS. 14A and 14B.

(5) Step of Forming Ridges and Electrodes and then Separating into a Piece

Next, as shown in FIGS. 14C and 14D, the p-type cladding layer 3 is etched into a predetermined shape to form ridges 4 for the respective light-emitting layers EL11, EL12, and EL13. In FIG. 14C, the thickness from the top face of the cladding layer 2 to the top face of the ridge 4 (an upper surface in a side of the p-side electrode 7P shown in FIG. 9A) is exaggerated; the ridge 4, which is formed by etching, has a height (distance in the thickness direction) of, for example, approximately 1 μm. Then, a passivation oxide film (not shown) such as SiO₂ is formed, and openings in the oxide film are provided at the top face of the ridge using photolithography and etching techniques, forming the p-type electrodes 7P on the openings. The GaAs substrate is then cleaved and the cleaved surface is provided with an edge face coating to form the semiconductor laser LD1 shown in FIG. 9A.

### (Relation Between the Oscillation Wavelength and the Composition Ratio (in Composition Ratio))

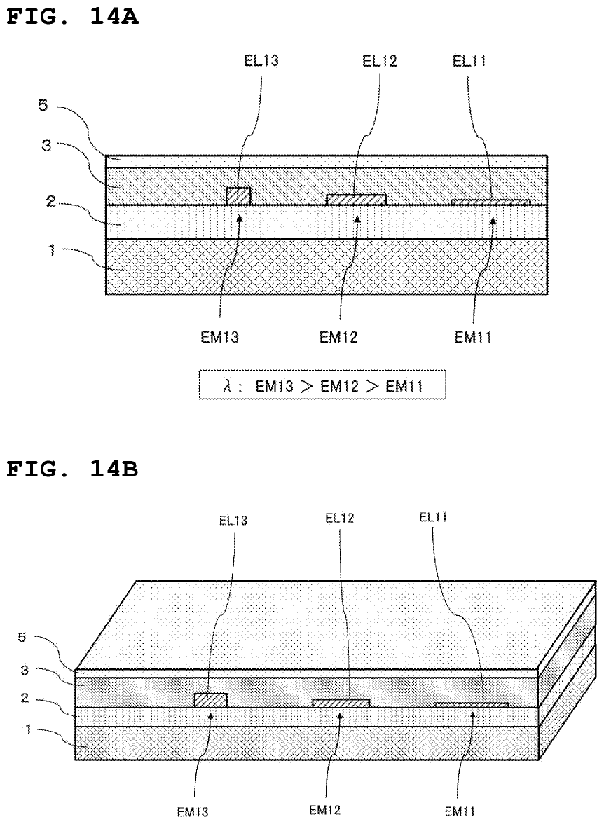

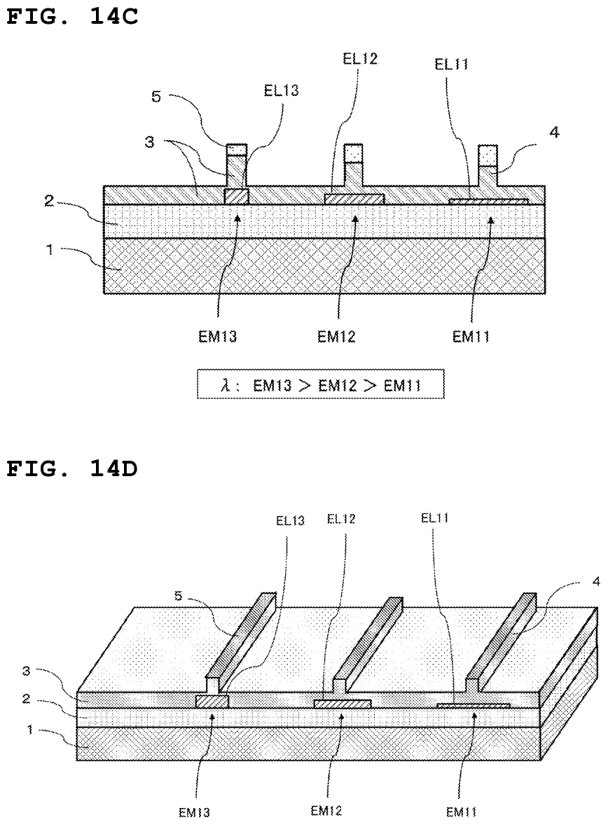

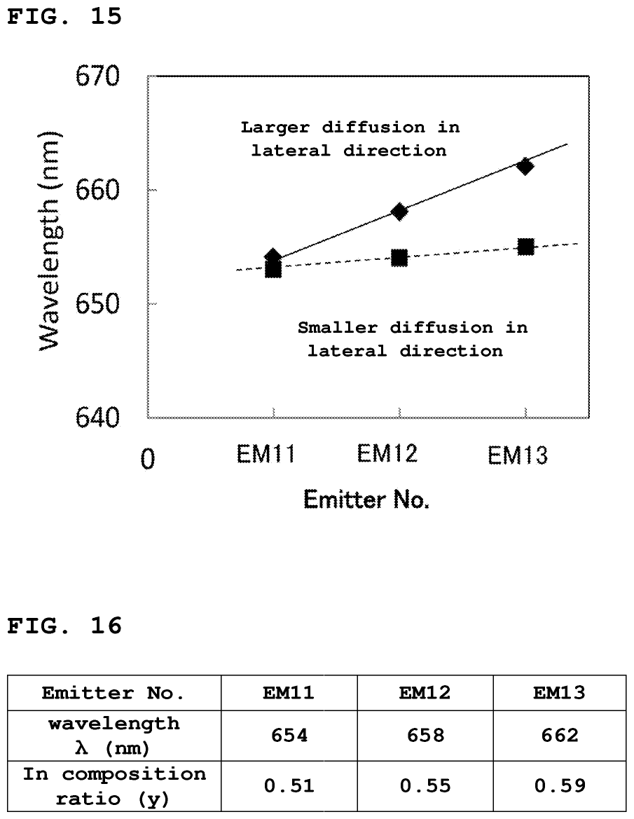

The relation between the oscillation wavelength and the composition ratio (In composition ratio) will now be explained with reference to FIGS. 15 to 17. FIGS. 15 and 16 are a graph and a table, respectively, indicating the relation between the In composition ratio in the quantum well layer QW formed by the selective growth method and the oscillation wavelength. FIG. 17 is a graph indicating the amount of strain of Ga_{1-y}In_{y}P with respect to the In composition ratio in the quantum well layer QW.

For the purpose of indicating the fundamental relation between the oscillation wavelength and the composition ratio (In composition ratio), the data in FIGS. 15 and 16 were obtained by forming a thick quantum well layer QW (for example, a thickness of 20 nm or more) so as to prevent the thickness of the quantum well layer QW from influencing on the oscillation wavelength. (The quantum well layer QW of the embodiment 2 has a thickness of 5 nm to 6 nm.) Hence, the data in FIGS. 15 and 16 do not fully match the data obtained using the configuration (i.e., dimension) of the semiconductor laser device LD1 of the embodiment 2.

FIG. 15 indicates the oscillation wavelength with respect to the light-emitting sections EM11, EM12 and EM13, which have different widths (corresponding to the opening widths EW of the mask layer MK in FIGS. 11A and 11B), in the case in which the selective growth condition is set to be a larger diffusion in the lateral direction (diamond-shaped plots) and the case in which the selective growth condition is set to be a smaller diffusion in the lateral direction (square-shaped plots). FIG. 16 indicates the specific numerical results of FIG. 15. As shown in FIG. 15, the smaller diffusion in the lateral direction (square-shaped plots) causes virtually no variation in the oscillation wavelength in the light-emitting sections EM11, EM12 and EM13. In contrast, the larger diffusion in the lateral direction (diamond-shaped plots) causes variation in the oscillation wavelength in each of the light-emitting sections EM11, EM12 and EM13. Specifically, as shown in FIG. 16, the light-emitting section EM11 has the quantum well layer QW, which is composed of (AlₓGa₁₋ₓ)_{1-y}In_{y}P, having the In composition ratio (y) of 0.51, and an oscillation wavelength of 654 nm. The light-emitting section EM12 has the quantum well layer QW, which is composed of (AlₓGa₁₋ₓ)_{1-y}In_{y}P, having the In composition ratio (y) of 0.55, and an oscillation wavelength of 658 nm. The light-emitting section EM13 has the quantum well layer QW, which is composed of (AlₓGa₁₋ₓ)_{1-y}In_{y}P, having the In composition ratio (y) of 0.59, and an oscillation wavelength of 662 nm. Therefore, the oscillation wavelength is controlled by varying the In composition ratio (y) of the quantum well layer QW, which is composed of (AlₓGa₁₋ₓ)_{1-y}In_{y}P. The In composition ratio described above refers to the value in the active layer EL located below the ridge 4.

FIG. 17 is a graph indicating the amount of strain of Ga_{1-y}In_{y}P with respect to the In composition ratio in the quantum well layer QW. As shown in FIG. 17, the amount of strain varies by varying the In composition ratio. The amount of strain is 0 when the In composition ratio is 0.5. As shown in FIGS. 15 and 16, the oscillation wavelength is adjusted by the In composition ratio; however, the large amount of strain suffers the quality of the active layer, decreasing the emission efficiency. Hence, although the amount of strain depends on the thickness of Ga_{1-y}In_{y}P, the quantum well layer QW with a thickness of approximately 10 nm preferably has the amount of strain in the range of −2.0% to +2.5%, thereby the In composition ratio thereof is between 0.35 to 0.65. In other words, the In composition ratio of the quantum well layer QW of the light-emitting layer EL is preferably selected in the range of 0.35 to 0.65. When the In composition ratio of the quantum well layer QW is 0.35, the oscillation wavelength is 620 nm; the In composition ratio thereof is 0.65, the oscillation wavelength is 690 nm. Therefore, the oscillation wavelength is controlled at least in the range of 620 nm to 690 nm by varying the In composition ratio.

Next, in another embodiment 2, explained is the background that the present inventors have reached the idea that the oscillation wavelength is adjusted (controlled) by varying the composition ratio of the crystal of the light-emitting layer EL, in addition to by varying the thickness of the light-emitting layer.

The present inventors acknowledged that methods of varying the wavelength included varying the thickness of the light-emitting layer and varying the composition of the light-emitting layer. Moreover, the present inventors, through their consideration, found that the laser beam having a shorter wavelength allows the amount of wavelength to vary less with respect to the thickness of the light-emitting layer. For example, the present inventors concluded that in the case that the quantum well layer QW having a thickness of around 5 nm for emitting a wavelength band of the red range, adjusting only the thickness of the layer has a limit on the amount of variation in the wavelength (adjustment range), thereby adjusting only the thickness of the layer may not sufficiently secure the wavelength difference.

Hence, the present inventors focus on varying the energy band gap using the difference in the composition of the light-emitting layer to control the wavelength, in addition to varying the thickness of the light-emitting layer.

The active layer of (AlₓGa₁₋ₓ)_{1-y}In_{y}P for emitting a red wavelength band involves a cladding layer having a mixed crystal of (AlₓGa₁₋ₓ)_{1-y}In_{y}P constituted by at least Al and In. Increasing Al composition ratio (doping amount) enables variation of the energy band; however, the technical difficulties on the process may arise shown on the following (1) and (2). (1) Al is highly susceptible to be oxidized, making it difficult to treat the interface in selective growth process. (2) Al easily forms poly deposits on the mask layer during the selective growth, making it difficult to control the composition of the crystals to be grown. Thereby, the present inventors have found that adjusting the composition ratio of the crystal, especially the In composition ratio thereof, is effective in varying the energy band gap in terms of both the control of the amount of wavelength variation and the process availability. Therefore, varying the In composition ratio in the composition constituting the crystal layer enables the single laser device to readily emit multiple laser beams having different wavelengths.

### Advantage of the Embodiment 2

The semiconductor laser device LD1 according to another embodiment 2 also exhibits the advantages similar to that of the semiconductor laser device LD01 according to another embodiment 1. In the semiconductor laser device LD1 according to another embodiment 2, the three light-emitting sections EM11, EM12, EM13 emit laser beams having different wavelengths by forming the light-emitting layers with different composition ratios in accordance with the widths of the light-emitting layers EL11, El12, EL13. This configuration makes it possible to suppress the image quality degradation due to the interference of laser beam and further improve visual sensitivity and image quality such as a wide color gamut, high resolution and a wide viewing angle.

### Another Embodiment 3

The following describes the semiconductor laser device according to another embodiment 3, which is applied to a display for an optical apparatus such as a head-mounted display (HMD), head-up display or AR glasses. The semiconductor laser device according to another embodiment 3 has the same configuration as the semiconductor laser device according to another embodiment 1 and 2, except that a high frequency current is further superimposed on the current applied to the semiconductor laser device. Thus, unless otherwise mentioned, the following mainly describes the points that are different from those of the embodiment 1 and 2, and repetition of the same explanation is omitted.

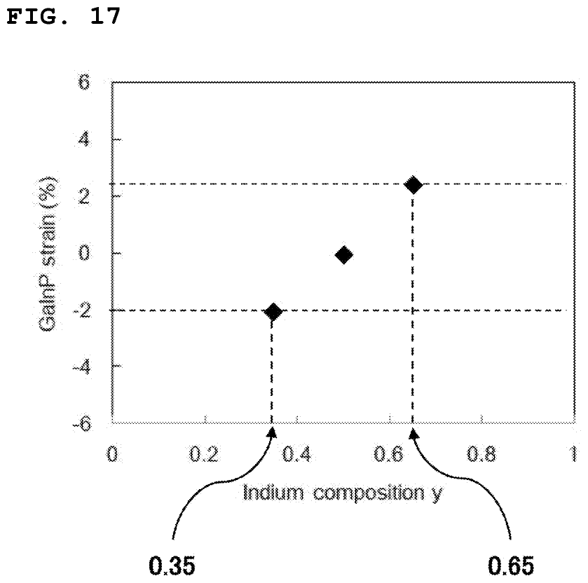

FIG. 18 is a system schematic diagram of an optical apparatus using a semiconductor laser device according to another embodiment 3.

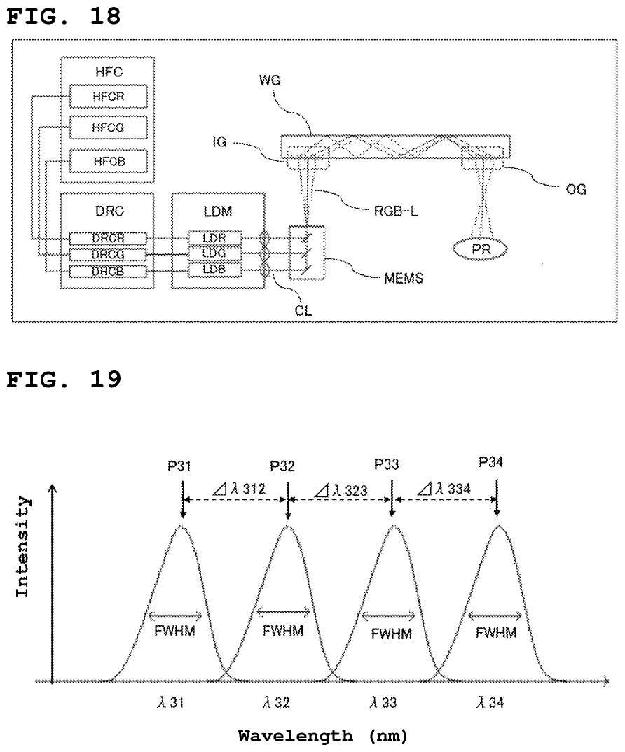

FIG. 19 is a schematic view illustrating a spectral distribution of a laser beam of the semiconductor laser device according to another embodiment 3.

The optical apparatus shown in FIG. 18 has a LD module (LDM) composed of red, green and blue LDs (LDR, LDG, LDB) that emit laser light in the three colors of RGB (red, green, blue). The LD module (LDM) is connected to a LD drive circuit (DRC) that includes LD drive circuits for red, green and blue (DRCR, DRCG, DRCB) that applies current to the red LD (LDR), green LD (LDG) and blue LD (LDB) to control the drive, respectively. The LD drive circuit (DRC) is connected to a high frequency superimposition circuit (HFC) that includes high frequency superimposition circuits for red, green and blue (HFCR, HFCG, HFCB) that superimpose high frequency current on the LD drive circuit for red, green and blue (DRCR, DRCG, DRCB), respectively. The laser beams of red, green and blue emitted from the LD module (LDM) pass through collimated lens (CL) and are incident on a MEMS, which is a spatial modulation device for displaying images. The laser beam (RGB-L) of the three colors (red, green, blue) emitted from the MEMS is incident on a waveguide WG at an incoming grating (IG). The laser beam passes through the waveguide WG, emits at an outgoing grating (OG), and projects to a projection part (PR) such as a retina.

FIG. 19 shows a spectral distribution of a laser beam of the red LD (LDR) in the laser beams of the three colors (red, green, blue). As shown in FIG. 19, since the red LD (LDR) is driven by the drive current that is superimposed with high frequency current using the high frequency superimposition circuit for red (HFCR), the laser beam emitted from the red LD (LDR) is expanded to a full width at half maximum (FWHM) of 1.0 nm. The respective wavelengths of the laser beam emitted from the red laser (LDR) are, for example, λ31=640 nm, λ32=643 nm, λ33=646 nm, λ34=649 nm. In other word, the wavelength intervals (Δλ312, Δλ323, Δλ334) between the peak wavelengths (λ31 to λ34) corresponding to the peak value (P31 to P34) is set to 3 nm.

As described above, applying the high frequency superimposition to the laser device enables the expansion of the full width at half maximum (FWHM) of the laser light spectral. Hence, this spectral expansion makes the overall spectral distribution to be more uniform, compared with the case of the narrow full width at half maximum (FWHM) of the spectral when no high frequency superimposition is applied. Therefore, with the spectral distribution being uniform, color differences (color temperature differences) caused by wavelength differences within the same image are made less likely to occur, improving image quality.

When expanding the spectral width using only high-frequency superimposition, driving a pulse with its pulse width shorter than 15 ns is necessary to expand the full width at half maximum beyond 1.5 nm. Furthermore, a drive circuit that accomplishes the high current drive and the short pulse drive is technically challenging and difficult to be implemented. In this case, the spectral distribution remains approximately 1.5 nm. However, as shown in another embodiment 3, employing the multiple lasers having different peak wavelengths, in addition to high frequency super imposition, is effective in broadening the spectral width, thereby reducing the fringe and improving the image quality.

As described above, the invention made by the present inventors have been specifically described in accordance with the embodiment; however, the present invention is not limited to the above-described embodiments, and may be modified in various ways without departing from the gist thereof. For example, the semiconductor laser device of the red range is described in the above-described embodiments; however, the description can also be applied to semiconductor laser devices of other color regions as long as the color regions are a visible light region other than red. In the above-described embodiment, the width, thickness and composition ratio of the light-emitting layer are used to for changing peak wavelength; however, a diffraction grating may be used for changing peak wavelength of the laser. In addition, a semiconductor laser device of GaAs (substrate)/AlGaInP (crystal layer) is described in the above-mentioned embodiment; however, the description can also be applied to semiconductor laser devices of GaAs/InGaAsP.

Moreover, described is the case in which the single semiconductor laser device emits three or four laser beams with different wavelengths in the above embodiment; however, the single semiconductor laser device may emit five or more laser beams.

In addition, even when the exemplary specific numerical value is described, a numerical value may exceed the specific numerical value or fall short of the specific numerical value, unless it is clearly limited by the theory. In addition, with respect to a component in a layer/film or a structure, it may mean “B containing A as a major component” and so on, and does not exclude the inclusion of other components.

The above-described embodiments include the following aspects.

### (Aspect 1)

A semiconductor laser device includes:
a substrate having a main surface;
a first cladding layer with a first conductive type and a second cladding layer with a second conductive type, which are stacked over the main surface of the substrate; and
a light-emitting layer that is formed between the first cladding layer and the second cladding layer, and is formed on a first surface parallel to the main surface of the substrate;
the light-emitting layer has a plurality of light-emitting sections emitting laser beams in a red range; and
among the laser beams emitted from the light-emitting sections, the difference between a peak wavelength in an optical spectrum of at least one laser beam and a peak wavelength in an optical spectrum of the other laser beams is 1.5 nm or more.

### (Aspect 2)

The semiconductor laser device according to Aspect 1, the light-emitting layer emits a laser beam having a wavelength of 600 nm or more and 700 nm or less.

### (Aspect 3)

The semiconductor laser device according to Aspect 1, the semiconductor laser device has at least three light-emitting sections.

### (Aspect 4)

The semiconductor laser device according to Aspect 1, among the laser beams emitted from the light-emitting sections, the difference between the peak wavelength in the optical spectrum of at least one laser beam and the peak wavelength in the optical spectrum of the other laser beams is 3 nm or more and 30 nm or less.

### (Aspect 5)

The semiconductor laser device according to Aspect 1, among the laser beams emitted from the light-emitting sections, the difference between the peak wavelength in the optical spectrum of a laser beam having a longest wavelength and the peak wavelength in the optical spectrum of a laser beam having a shortest wavelength is 1.5 nm or more and 30 nm or less.

### (Aspect 6)

The semiconductor laser device according to Aspect 1, the light-emitting sections are spaced apart with an interval of 5 μm or more and 100 μm or less between the light-emitting sections adjacent each other.

### (Aspect 7)

The semiconductor laser device according to Aspect 1, the semiconductor laser device is a Febry-Perot laser diode and each of the laser beams emitted from the light-emitting sections has a spectral linewidth of 0.01 nm or more and 1 nm or less.

### (Aspect 8)

The semiconductor laser device according to Aspect 1, the semiconductor laser device is a distributed feedback laser diode or a distributed Bragg reflector laser diode, and each of the laser beams emitted from the light-emitting sections has a spectral linewidth of 0.0001 nm or more and 0.01 nm or less.

### (Aspect 9)

A semiconductor laser device includes:
a substrate having a main surface; and
a plurality of light-emitting sections that are formed over the main surface of the substrate, and emit laser beams having a wavelength of 600 nm or more and 700 nm or less;
among the laser beams emitted from the light-emitting sections, the difference between a peak wavelength in an optical spectrum of at least one laser beam and a peak wavelength in an optical spectrum of the other laser beams is 1.5 nm or more;
the laser beams have spectral widths that are expanded by applying a current superimposed with a high frequency current to the light-emitting sections; and
the laser beams emitted from the light-emitting sections are projected to a projection part through a waveguide.

### (Aspect 10)

An optical apparatus includes:
a semiconductor laser device;
a drive circuit that drives the semiconductor laser device by applying a current to the semiconductor laser device;
a high frequency superimposition circuit that is connected to the drive circuit;
a waveguide that guides a laser beam emitted from the semiconductor laser device; and
a projector part to which the laser beam guided through the waveguide is projected;
the semiconductor laser device includes a plurality of light-emitting sections that are formed over a substrate and emit the laser beams having a wavelength of 600 nm or more and 700 nm or less;
among the laser beams emitted from the light-emitting sections, the difference between a peak wavelength in an optical spectrum of at least one laser beam and a peak wavelength in an optical spectrum of the other laser beams is 1.5 nm or more; and
the laser beams have spectral widths that are expanded by superimposing a high frequency current on the current by the high frequency superimposition circuit.

What is claimed is:

1. A semiconductor laser device comprising:
a substrate having a main surface;
a first cladding layer with a first conductive type and a second cladding layer with a second conductive type, which are stacked over the main surface of the substrate; and
a light-emitting layer that is formed between the first cladding layer and the second cladding layer, and is formed on a first surface parallel to the main surface of the substrate;
wherein the light-emitting layer has a plurality of light-emitting regions emitting laser beams in a red range; and
among the laser beams emitted from the light-emitting regions, the difference between a peak wavelength in an optical spectrum of at least one laser beam and a peak wavelength in an optical spectrum of the other laser beams is 1.5 nm or more.

2. The semiconductor laser device according to claim 1, wherein the light-emitting layer emits a laser beam having a wavelength of 600 nm or more and 700 nm or less.

3. The semiconductor laser device according to claim 1, wherein the semiconductor laser device has at least three light-emitting regions.

4. The semiconductor laser device according to claim 1, wherein among the laser beams emitted from the light-emitting regions, the difference between the peak wavelength in the optical spectrum of at least one laser beam and the peak wavelength in the optical spectrum of the other laser beams is 3 nm or more and 30 nm or less.

5. The semiconductor laser device according to claim 1, wherein among the laser beams emitted from the light-emitting regions, the difference between the peak wavelength in the optical spectrum of a laser beam having a longest wavelength and the peak wavelength in the optical spectrum of a laser beam having a shortest wavelength is 1.5 nm or more and 30 nm or less.

6. The semiconductor laser device according to claim 1, wherein the light-emitting regions are spaced apart with an interval of 5 μm or more and 100 μm or less between the light-emitting regions adjacent each other.

7. The semiconductor laser device according to claim 1, wherein each of the laser beams emitted from the light-emitting regions has a spectral linewidth of 0.01 nm or more and 1 nm or less.

8. The semiconductor laser device according to claim 1, wherein each of the laser beams emitted from the light-emitting regions has a spectral linewidth of 0.0001 nm or more and 0.01 nm or less.

9. A semiconductor laser device comprising:
a substrate having a main surface; and
a plurality of light-emitting regions that are formed over the main surface of the substrate, and emit laser beams having a wavelength of 600 nm or more and 700 nm or less;
wherein among the laser beams emitted from the light-emitting regions, the difference between a peak wavelength in an optical spectrum of at least one laser beam and a peak wavelength in an optical spectrum of the other laser beams is 1.5 nm or more;
the laser beams have spectral widths that are expanded by applying a current superimposed with a high frequency current to the light-emitting regions; and
the laser beams emitted from the light-emitting regions are projected to a projection part through a waveguide.

10. An optical apparatus comprising:
a semiconductor laser device;
a drive circuit that drives the semiconductor laser device by applying a current to the semiconductor laser device;
a high frequency superimposition circuit that is connected to the drive circuit;
a waveguide that guides a laser beam emitted from the semiconductor laser device; and
a projector part to which the laser beam guided through the waveguide is projected;
wherein the semiconductor laser device comprises a plurality of light-emitting regions that are formed over a substrate and emit the laser beams having a wavelength of 600 nm or more and 700 nm or less;
among the laser beams emitted from the light-emitting regions, the difference between a peak wavelength in an optical spectrum of at least one laser beam and a peak wavelength in an optical spectrum of the other laser beams is 1.5 nm or more; and
the laser beams have spectral widths that are expanded by superimposing a high frequency current on the current by the high frequency superimposition circuit.
